(19) United States
(12) Patent Application Publication
(10) Pub. No.: US 2026/0293405 A1
(43) Pub. Date: Sep. 24, 2026

(54) Light-Emitting Substrate and Display Module

(71) Applicants: BOE MLED Technology Co., Ltd., Beijing (CN); BOE TECHNOLOGY GROUP CO., LTD., Chaoyang District, Beijing (CN)

(72) Inventors: Naiwei Liu, Beijing (CN); Chao Tian, Beijing (CN); Yuanhao Sun, Beijing (CN); Haiwei Sun, Beijing (CN); Meiling Jin, Beijing (CN); Xiaozhou Liu, Beijing (CN); Tsungchieh Kuo, Beijing (CN); Jiajia Shen, Beijing (CN)

(21) Appl. No.: 18/995,439

(22) PCT Filed: Mar. 29, 2024
(86) PCT No.: PCT/CN2024/085065

§ 371 Date: Jan. 16, 2025

(51) Int. Cl. H10H 29/853; H10H 29/856

(52) U.S. Cl. CPC H10H 29/853; H10H 29/856

(57) ABSTRACT

A light-emitting substrate. The light-emitting substrate includes a substrate, a cover plate and a plurality of light-emitting elements located on the substrate. The plurality of light-emitting elements are located between the substrate and the cover plate. The cover plate includes a plurality of lens structures protruding toward the substrate. Orthogonal projections of centers of the plurality of lens structures on the substrate are located outside orthogonal projections of the plurality of light-emitting elements on the substrate, and an orthogonal projection of at least one of the plurality of lens structures on the substrate is located between the orthogonal projections of adjacent light-emitting elements in plurality of light-emitting elements on the substrate.

### CROSS-REFERENCE TO RELATED APPLICATION

This application is the United States national phase of International Patent Application No. PCT/CN2024/085065, filed Mar. 29, 2024, the disclosure of which is hereby incorporated by reference in its entirety.

### BACKGROUND OF THE INVENTION

### Field of the Invention

The present disclosure relates to the field of display technologies, and in particular, to a light-emitting substrate and a display module.

### Description of Related Art

With the development of light-emitting diode technology, mini light-emitting diodes (Mini-LEDs) and micro light-emitting diodes (Micro-LEDs) have been widely used. Mini-LEDs and Micro-LEDs have good performance in terms of brightness, service life, contrast, response time, energy consumption, viewing angle and resolution, and have the advantages of self-luminescence, simple structure, small volume and energy conservation, so that Mini-LEDs and Micro-LEDs are regarded as the next generation of display technology.

### SUMMARY OF THE INVENTION

In an aspect, a light-emitting substrate is provided. The light-emitting substrate includes a substrate, a cover plate and a plurality of light-emitting elements located on the substrate. The plurality of light-emitting elements are located between the substrate and the cover plate. The cover plate includes a plurality of lens structures protruding toward the substrate. Orthogonal projections of centers of the plurality of lens structures on the substrate are located outside orthogonal projections of the plurality of light-emitting elements on the substrate, and an orthogonal projection of at least one of the plurality of lens structures on the substrate is located between the orthogonal projections of adjacent light-emitting elements in the plurality of light-emitting elements on the substrate.

In some embodiments, the light-emitting substrate further includes a sealing portion and a filling portion, the sealing portion, the substrate and the cover plate together form a closed space surrounding the filling portion. A refractive index of the filling portion is less than a refractive index of the plurality of lens structures.

In some embodiments, the filling portion is gas.

In some embodiments, the cover plate further includes an extension portion extending in a plane extending parallel to the substrate. The extension portion is located on a side of the plurality of lens structures away from the substrate, and the extension portion is connected to the plurality of lens structures.

In some embodiments, the plurality of lens structures and the extension portion are a one-piece structure.

In some embodiments, a material of the plurality of lens structures includes at least one of transparent glass and transparent resin; and/or, a material of the extension portion includes at least one of transparent glass and transparent resin.

In some embodiments, a surface of a region of the cover plate located between adjacent lens structures in the plurality of lens structures facing the substrate is conformal with an extending surface of the substrate.

In some embodiments, a surface of a region of the cover plate located between adjacent lens structures in the plurality of lens structures facing the substrate is a plane.

In some embodiments, the lens structure has an area of a section that decreases in a direction towards the substrate. An extending direction of the section is parallel to an extending direction of the substrate opposite to the lens structure.

In some embodiments, the light-emitting substrate further includes a light-emitting region defined by outer contours of outermost two or more light-emitting elements in the plurality of light-emitting elements. The light-emitting substrate further includes first support pillar(s) located between the substrate and the cover plate, and the first support pillar is in contact with both the substrate and the cover plate. Orthogonal projections of the first support pillars on the substrate are disposed around the light-emitting region.

In some embodiments, the light-emitting substrate further includes a sealing portion and a filling portion, the sealing portion, the substrate and the cover plate together form a closed space surrounding the filling portion. The orthogonal projections of the first support pillars on the substrate are located between an orthogonal projection of the sealing portion on the substrate and the light-emitting region.

In some embodiments, the plurality of lens structures are all lens structures existing on the cover plate.

In some embodiments, in a thickness direction of at least one of the plurality of light-emitting elements, a minimum distance from the lens structure to the substrate is less than or equal to a distance from an end of the light-emitting element away from the substrate to the substrate.

In some embodiments, the plurality of light-emitting elements include a plurality of light-emitting element groups, a light-emitting element group in the plurality of light-emitting element groups includes at least one light-emitting element in the plurality of light-emitting elements. The plurality of light-emitting element groups are arranged in a plurality of rows and a plurality of columns. Two adjacent light-emitting element groups respectively belonging to two adjacent rows are disposed in a staggered manner in a first direction, and two adjacent light-emitting element groups respectively belonging to two adjacent columns are disposed in a staggered manner in a second direction. The first direction is a row direction in which the plurality of light-emitting element groups are arranged, and the second direction is a column direction in which the plurality of light-emitting element groups are arranged. The orthogonal projection of the lens structure on the substrate is located between adjacent light-emitting element groups in the plurality of light-emitting element groups and has a gap from the adjacent light-emitting element groups.

In some embodiments, the light-emitting element group includes a light-emitting element in the plurality of light-emitting elements. The plurality of light-emitting elements include a plurality of first light-emitting elements, a plurality of second light-emitting elements, and a plurality of third light-emitting elements. One of the first light-emitting element, the second light-emitting element, and the third light-emitting element is configured to emit red light, another of the first light-emitting element, the second light-emitting element, and the third light-emitting element is configured to emit green light, and yet another of the first light-emitting element, the second light-emitting element, and the third light-emitting element is configured to emit blue light. A line connecting centers of orthogonal projections of the first light-emitting element, the second light-emitting element, and the third light-emitting element that are closest to each other on the substrate is in a shape of a triangle.

In some embodiments, a maximum length of the orthogonal projection of the lens structure on the substrate in the first direction is less than or equal to a distance between two light-emitting elements adjacent to the lens structure in the first direction; and/or, a maximum length of the orthogonal projection of the lens structure on the substrate in the second direction is less than or equal to a distance between two light-emitting elements adjacent to the lens structure in the second direction.

In some embodiments, in the first direction, the orthogonal projection of the center of the lens structure on the substrate has a same gap from two light-emitting elements adjacent to the lens structure in the plurality of light-emitting elements; and/or, in the second direction, the orthogonal projection of the center of the lens structure on the substrate has a same gap from two light-emitting elements adjacent to the lens structure in the plurality of light-emitting elements.

In some embodiments, the light-emitting element includes a first semiconductor layer, a light-emitting layer and a second semiconductor layer that are sequentially stacked in a direction away from the substrate. In a thickness direction of the light-emitting element, a minimum distance from the lens structure to the substrate is less than or equal to a distance from a surface of the light-emitting layer away from the substrate to the substrate. Alternatively, in the thickness direction of the light-emitting element, the minimum distance from the lens structure to the substrate is greater than the distance from the surface of the light-emitting layer away from the substrate to the substrate, and a difference between the minimum distance from the lens structure to the substrate and the distance from the surface of the light-emitting layer away from the substrate to the substrate is less than or equal to 10 μm.

In some embodiments, a surface of the lens structure proximate to the substrate is a curved surface, and a curvature of the curved surface is less than 0.15.

In some embodiments, a surface of the lens structure proximate to the substrate is a curved surface, and a curvature of the curved surface is within a range of 0.05 to 0.1, inclusive.

In some embodiments, the orthogonal projection of the lens structure on the substrate is in a shape of one of a circle, an ellipse and a rectangle. Alternatively, the surface of the lens structure proximate to the substrate is a spherical surface.

In some embodiments, in the first direction, a distance between the center of the orthogonal projection of the lens structure on the substrate and the first light-emitting element is greater than a distance between the center of the orthogonal projection of the lens structure on the substrate and the second light-emitting element, and is greater than a distance between the center of the orthogonal projection of the lens structure on the substrate and the third light-emitting element; and/or, in the second direction, a distance between the center of the orthogonal projection of the lens structure on the substrate and the first light-emitting element is greater than a distance between the center of the orthogonal projection of the lens structure on the substrate and the second light-emitting element, and is greater than a distance between the center of the orthogonal projection of the lens structure on the substrate and the third light-emitting element.

In some embodiments, the plurality of light-emitting elements include a target light-emitting element. A viewing angle brightness of a first side of the target light-emitting element in a third direction is greater than a viewing angle brightness of a second side of the target light-emitting element in the third direction. The third direction is parallel to the first direction or the second direction. A lens structure in the plurality of lens structures is disposed on each of two sides of the target light-emitting element in the third direction. A distance between the orthogonal projection of the center of the lens structure located on the first side of the target light-emitting element on the substrate and the target light-emitting element is less than a distance between the orthogonal projection of the center of the lens structure located on the second side of the target light-emitting element on the substrate and the target light-emitting element. The target light-emitting element is at least one of the first light-emitting element, the second light-emitting element, and the third light-emitting element.

In some embodiments, the orthogonal projection of the lens structure on the substrate is in a shape of at least one of an ellipse and a rectangle. The lens structure has a long axis direction and a short axis direction, and a dimension of the lens structure in the long axis direction is greater than a dimension of the lens structure in the short axis direction. The lens structure located on a periphery of the first light-emitting element in the plurality of lens structures is a first lens structure. The long axis direction of the first lens structure is perpendicular to a direction of a line connecting the center of the first light-emitting element and the center of the first lens structure. In a case where the orthogonal projection of the lens structure on the substrate is in a shape of the ellipse, the long axis direction of the lens structure is the same as a long axis direction of the ellipse, and the short axis direction of the lens structure is the same as a short axis direction of the ellipse. In a case where the orthogonal projection of the lens structure on the substrate is in a shape of the rectangle, the long axis direction of the lens structure is the same as a long side direction of the rectangle, and the short axis direction of the lens structure is the same as a short side direction of the rectangle.

In some embodiments, the orthogonal projection of the lens structure on the substrate is in a shape of at least one of an ellipse and a rectangle. The lens structure has a long axis direction and a short axis direction, and a dimension of the lens structure in the long axis direction is greater than a dimension of the lens structure in the short axis direction. The plurality of lens structures are arranged in a plurality of rows, and one row includes two or more lens structures arranged in the first direction. The long axis directions of the lens structures in a same row are parallel to each other, and the long axis directions of the lens structures in two adjacent rows intersect with each other. In a case where the orthogonal projection of the lens structure on the substrate is in a shape of the ellipse, the long axis direction of the lens structure is the same as a long axis direction of the ellipse, and the short axis direction of the lens structure is the same as a short axis direction of the ellipse. In a case where the orthogonal projection of the lens structure on the substrate is in a shape of the rectangle, the long axis direction of the lens structure is the same as a long side direction of the rectangle, and the short axis direction of the lens structure is the same as a short side direction of the rectangle.

In some embodiments, the first light-emitting element is configured to emit red light; one of the second light-emitting element and the third light-emitting element is configured to emit green light, and another of the second light-emitting element and the third light-emitting element is configured to emit blue light.

In some embodiments, the plurality of light-emitting elements include a plurality of light-emitting element groups, and each light-emitting element group in the plurality of light-emitting element groups includes at least two light-emitting elements in the plurality of light-emitting elements. A gap between two adjacent light-emitting elements in a same light-emitting element group is less than a gap between two adjacent light-emitting element groups in the plurality of light-emitting element groups. The orthogonal projection of the lens structure on the substrate is located between the two adjacent light-emitting element groups and has a gap from the adjacent light-emitting element groups.

In some embodiments, the plurality of light-emitting elements include a plurality of first light-emitting elements, a plurality of second light-emitting elements, and a plurality of third light-emitting elements. One of the first light-emitting element, the second light-emitting element, and the third light-emitting element is configured to emit red light, another of the first light-emitting element, the second light-emitting element, and the third light-emitting element is configured to emit green light, and yet another of the first light-emitting element, the second light-emitting element, and the third light-emitting element is configured to emit blue light. The light-emitting element group includes the first light-emitting element, the second light-emitting element, and the third light-emitting element arranged adjacent in a first direction. A region defined by an outer contour of the light-emitting element group is a first region, and the first direction is a row direction in which the plurality of light-emitting elements are arranged. The orthogonal projection of the lens structure on the substrate is in a shape of at least one of an ellipse and a rectangle. The lens structure has a long axis direction and a short axis direction, and a dimension of the lens structure in the long axis direction is greater than a dimension of the lens structure in the short axis direction. The long axis direction of the lens structure is parallel to an extending direction of a side of the first region proximate to the lens structure. In a case where the orthogonal projection of the lens structure on the substrate is in a shape of the ellipse, the long axis direction of the lens structure is the same as a long axis direction of the ellipse, and the short axis direction of the lens structure is the same as a short axis direction of the ellipse. In a case where the orthogonal projection of the lens structure on the substrate is in a shape of the rectangle, the long axis direction of the lens structure is the same as a long side direction of the rectangle, and the short axis direction of the lens structure is the same as a short side direction of the rectangle.

In some embodiments, a lens structure in the plurality of lens structures is disposed between two adjacent light-emitting element groups in the first direction, and a lens structure in the plurality of lens structures is disposed between two adjacent light-emitting element groups in the second direction. End portions proximate to each other, of four lens structures located among four light-emitting element groups in two adjacent rows and two adjacent columns form a second region. The light-emitting substrate further includes a plurality of second support pillars, a second support pillar in the plurality of second support pillars is located in the second region, and the second support pillars are in contact with both the substrate and the cover plate.

In some embodiments, sizes of the plurality of light-emitting elements are less than or equal to 50 μm; and/or, a gap between two adjacent light-emitting elements in a first direction in the plurality of light-emitting elements is within a range of 6 μm to 300 μm, inclusive, the plurality of light-emitting elements include a plurality of light-emitting element groups arranged in a plurality of rows and a plurality of columns, the first direction is a row direction in which the plurality of light-emitting element groups are arranged; and/or, a gap between two adjacent light-emitting elements in a second direction in the plurality of light-emitting elements is within a range of 6 μm to 300 μm, inclusive, the plurality of light-emitting elements include the plurality of light-emitting element groups arranged in the plurality of rows and the plurality of columns, the second direction is a column direction in which the plurality of light-emitting element groups are arranged.

In some embodiments, ends of the plurality of light-emitting elements proximate to the cover plate each have a gap from the cover plate.

In some embodiments, the light-emitting substrate further includes a sealing portion and a filling portion, the sealing portion, the substrate and the cover plate together form a closed space surrounding the filling portion; and/or, a refractive index of the plurality of lens structures is greater than or equal to 1.5.

In some embodiments, the light-emitting substrate is a display substrate. The light-emitting substrate further includes a driving circuit layer located on the substrate, and the driving circuit layer is electrically connected to the plurality of light-emitting elements and is used to provide a driving signal for the plurality of light-emitting elements.

In some embodiments, the plurality of light-emitting elements are a mini light-emitting diode (Mini-LED) or a micro light-emitting diode (Micro-LED).

In another aspect, a display module is provided. The display module includes the light-emitting substrate as described in any one of the above embodiments.

In yet another aspect, a display apparatus is provided. The display apparatus includes a liquid crystal display panel and the light-emitting substrate as described in any one of the above embodiments. The liquid crystal display panel is disposed on a light-exit side of the light-emitting substrate.

In yet another aspect, a display apparatus is provided. The display apparatus includes the above light-emitting substrate, and a first polarizer, a transflective film, a first lens, a second polarizer, a reflective polarizer and a second lens that are sequentially stacked on a light-exit side of the light-emitting substrate.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art may obtain other drawings according to these accompanying drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a diagram showing a structure of a display apparatus, in accordance with some embodiments;

FIG. 2 is a diagram showing another structure of a display apparatus, in accordance with some embodiments;

FIG. 3 is a diagram showing yet another structure of a display apparatus, in accordance with some embodiments;

FIG. 4 is a plan view showing a structure of a light-emitting substrate, in accordance with some embodiments;

FIG. 5 is a sectional view taken along the section line A-A in FIG. 4;

FIG. 6A is a diagram showing a structure of a light-emitting element, in accordance with some embodiments;

FIG. 6B is a diagram showing another structure of a light-emitting element, in accordance with some embodiments;

FIG. 7 is a diagram showing a light path of light passing through a lens structure, in accordance with some embodiments;

FIG. 8A is a diagram showing a relative position between a lens structure and a light-emitting element, in accordance with some embodiments;

FIG. 8B is a diagram showing another relative position between a lens structure and a light-emitting element, in accordance with some embodiments;

FIG. 8C is a diagram showing yet another relative position between a lens structure and a light-emitting element, in accordance with some embodiments;

FIG. 9 is a graph showing a viewing angle and luminous intensity of a light-emitting element in a case where a lens structure and a light-emitting element are at different positions, in accordance with some embodiments;

FIG. 10 is a graph showing a viewing angle and luminous intensity of a light-emitting element in a case of different curvatures, in accordance with some embodiments;

FIG. 11 is a diagram showing a positional arrangement of a lens structure and a light-emitting element, in accordance with some embodiments;

FIG. 12 is a graph showing a viewing angle and luminous intensity of a light-emitting element in a case where a lens structure has different gaps with a light-emitting element, in accordance with some embodiments;

FIG. 13 is a diagram showing another positional arrangement of a lens structure and a light-emitting element, in accordance with some embodiments;

FIG. 14 is a diagram showing yet another positional arrangement of a lens structure and a light-emitting element, in accordance with some embodiments;

FIG. 15 is a diagram showing yet another positional arrangement of a lens structure and a light-emitting element, in accordance with some embodiments;

FIG. 16 is a diagram showing yet another positional arrangement of a lens structure and a light-emitting element, in accordance with some embodiments;

FIG. 17 is a graph showing a viewing angle and luminous intensity of a light-emitting element in a case where a lens structure is disposed at different positions, in accordance with some embodiments;

FIG. 18 is a diagram showing yet another positional arrangement of a lens structure and a light-emitting element, in accordance with some embodiments;

FIG. 19 is a diagram showing yet another positional arrangement of a lens structure and a light-emitting element, in accordance with some embodiments;

FIG. 20A is diagram showing an arrangement in a case where a long axis direction of a lens structure is parallel to an extending direction of a side of a light-emitting element, in accordance with some embodiments;

FIG. 20B is diagram showing an arrangement in a case where a short axis direction of a lens structure is parallel to an extending direction of a side of a light-emitting element, in accordance with some embodiments;

FIG. 20C is a graph showing a viewing angle and luminous intensity of a light-emitting element in a case where a lens structure is disposed at different directions, in accordance with some embodiments;

FIG. 21 is a diagram showing yet another positional arrangement of a lens structure and a light-emitting element, in accordance with some embodiments;

FIG. 22 is a diagram showing yet another positional arrangement of a lens structure and a light-emitting element, in accordance with some embodiments;

FIG. 23 is a plan view showing another structure of a light-emitting substrate, in accordance with some embodiments;

FIG. 24 is a sectional view taken along the section line B-B in FIG. 23; and

FIG. 25 is a plan view showing yet another structure of a light-emitting substrate, in accordance with some embodiments.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the expression “connected”, and derivative thereof may be used. The term “connected” should be understood in a broad sense. For example, the term “connected” may represent a fixed connection, a detachable connection, or a one-piece connection, or may represent a direct connection, or may represent an indirect connection through an intermediate medium. The embodiments disclosed here are not necessarily limited to the content herein.

The phrase “A and/or B” includes following three combinations: only A, only B, and a combination of A and B.

The phrase “configured to” used herein means an open and inclusive expression, which does not exclude devices that are applicable to or configured to perform additional tasks or steps.

In addition, the phase “based on” as used herein is meant to be open and inclusive, since a process, a step, a calculation or other action that is “based on” one or more of stated conditions or values may, in practice, be based on additional conditions or values beyond those stated.

The term “about”, “substantially”, and “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular”, or “equal” as used herein includes a stated condition and a condition similar to the stated condition. A range of the similar condition is within an acceptable range of deviation, and the acceptable range of deviation is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Thus, variations in shape with respect to the accompanying drawings due to, for example, manufacturing technologies and/or tolerances may be envisaged. And the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in devices, and are not intended to limit the scope of the exemplary embodiments.

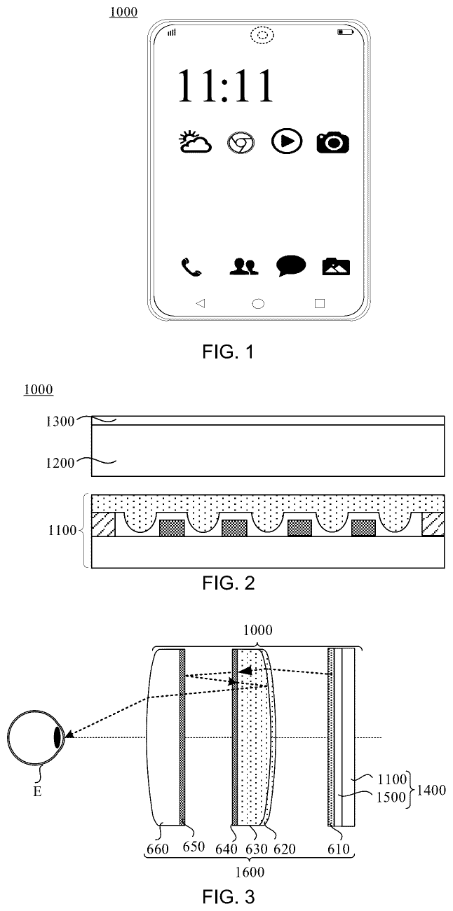

Referring to FIG. 1, a display apparatus 1000 is provided in embodiments of the present disclosure, and the display apparatus 1000 is a product having an image display function. For example, the display apparatus 1000 may be any apparatus displaying an image whether in motion (e.g., a video) or stationary (e.g., a still image), and regardless of text or image.

The display apparatus 1000 may be applied to a variety of electronic devices. For example, the display apparatus 1000 may include a mobile phone, a wireless device, a personal digital assistant (PDA), a wearable device, an augmented reality (AR) device, a virtual reality (VR) device, a hand-held or portable computer, a global positioning system (GPS) receiver/navigator, a camera, a moving picture experts group 4 (MP4) video player, a video camera, a game console, a watch, a clock, a calculator, a television monitor, a flat panel display, a computer monitor, an automobile display (e.g., an odometer display), a cockpit control and/or display, a display with camera views (e.g., a display of a rear-view camera in a vehicle), an electronic photo, an electronic billboard or sign, a projector, a packaging and aesthetic structure (e.g., a display for displaying an image of a piece of jewelry). For example, as shown in FIG. 1, the display apparatus 1000 may be a mobile phone.

The display apparatus 1000 may be a flat display apparatus, a curved display apparatus or a foldable display apparatus from the form of the display apparatus 1000. The display apparatus 1000 may be in a shape of a rectangle or a circle from the shape of the display apparatus 1000. In the following embodiments of the present disclosure, the present disclosure is schematically described by considering an example in which the display apparatus 1000 is in a shape of a rectangle and a flat display apparatus, but the embodiments of the present disclosure are not limited thereto, and any other display apparatus may also be considered as long as a same technical concept is applied.

The display apparatus 1000 includes a display module, and the display module may include a light-emitting substrate 1100 and a driving circuit board (not shown in the drawings). The driving circuit board is connected to the light-emitting substrate and configured to transmit control signals to the light-emitting substrate, so as to drive the light-emitting substrate to emit light. In addition, the display apparatus 1000 may further include a touch structure, an under-screen camera and an under-screen fingerprint recognition sensor, etc., so that the display apparatus 1000 may achieve a variety of different functions such as touch, taking pictures, video recording or fingerprint recognition. The structure of the display apparatus 1000 is not limited thereto, as long as a same technical concept is applied.

For example, the display apparatus 1000 may be a liquid crystal display (LCD) apparatus. Referring to FIG. 2, in a case where the display apparatus 1000 is a liquid crystal display apparatus, the display module may include a light-emitting substrate 1100, a liquid crystal display panel 1200, and an upper polarizer 1300 that are stacked. In this case, the light-emitting substrate 1100 may be a portion of a backlight module. The light-emitting substrate 1100 is located on a non-light-exit side of the liquid crystal display panel 1200 and configured to provide a light source to the liquid crystal display panel 1200. The light-emitting substrate 1100 may emit linearly polarized light (e.g., the light-emitting substrate 1100 further includes a polarizer), so as to emit linearly polarized light with a specific polarization direction toward the liquid crystal display panel 1200. The liquid crystal display panel 1200 includes a plurality of sub-pixels, each sub-pixel is configured to modulate the linearly polarized light incident therein, so as to adjust a polarization direction of light exiting from the sub-pixel. The upper polarizer 1300 is disposed on a light-exit side of the liquid crystal display panel 1200 and configured to filter the linearly polarized light exiting from each sub-pixel. As a result, the light with the same polarization direction as a polarizer optical axis direction of the upper polarizer 1300 exits from the upper polarizer 1300, and the light with a polarization direction perpendicular to the polarizer optical axis direction of the upper polarizer 1300 is blocked from exiting by the upper polarizer 1300, so that the display of different gray scales may be achieved and the image display may be further achieved.

For example, the display apparatus 1000 may also be a direct display apparatus (e.g., a micro light-emitting diode (Micro-LED) display apparatus or a mini light-emitting diode (Mini-LED) display apparatus). The display apparatus 1000 may include a light-emitting substrate 1100, and the light-emitting substrate 1100 may be directly used for image display.

For example, the display apparatus 1000 may also be a 3-dimensional (3D) display apparatus. In this case, referring to FIG. 3, a display module 1400 may include a light-emitting substrate 1100 and a linearly polarizer 1500 disposed on a light-exit side of the light-emitting substrate 1100. As a result, the display module may emit linearly polarized light with a specific polarization direction. The display apparatus 1000 may include the display module 1400 and optical modules 1600 sequentially stacked on a light-exit side of the display module 1400. The optical modules 1600 may include, for example, a first polarizer 610, a transflective film 620, a first lens 630, a second polarizer 640, a reflective polarizer 650, and a second lens 660 that are sequentially arranged in a light-exit direction of the light-emitting substrate 1100.

The first polarizer 610 and the second polarizer 640 may both be quarter-wave plates. The first lens 630 and the second lens 660 may increase an optical path of light exiting from the light-emitting substrate 1100 and may enlarge the images displayed by the light-emitting substrate 1100.

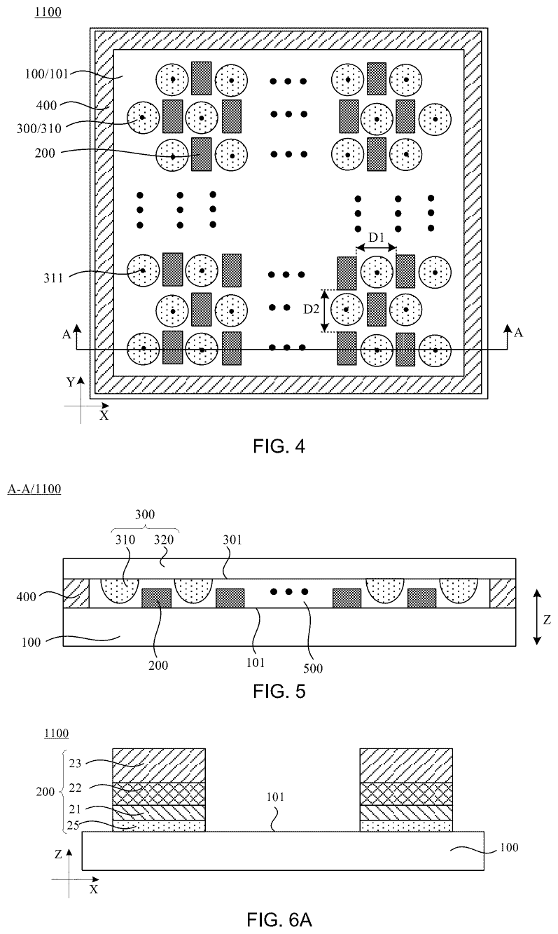

The following is briefly described by considering a light path of light emitted by the display apparatus 1000 and incident into human eyes E as an example. As shown in FIG. 3, light emitted by the display module 1400 may be linearly polarized light (e.g., transverse magnetic mode (TM) light). The polarized light is incident on the first polarizer 610 and exits from the first polarizer 610 after being converted into circularly polarized light. The circularly polarized light is incident on the transflective film 620. A part of circularly polarized light is transmitted by the transflective film 620, and incident on the second polarizer 640 after passing through the first lens 630. The part of circularly polarized light is converted into linearly polarized light (e.g., transverse electric mode (TE) light) by the second polarizer 640 and then incident on the reflective polarizer 650. The linearly polarized light is reflected by the reflective polarizer 650 and then incident on the second polarizer 640 again. The linearly polarized light is converted into circularly polarized light by the second polarizer 640 and then passes through the first lens 630 and incident on the transflective film 620. A part of circularly polarized light is reflected to the second polarizer 640 by the transflective film 620, and incident on the reflective polarizer 650 after being converted into linearly polarized light (e.g., TM light) by the second polarizer 640. The linearly polarized light passes through the reflective polarizer 650 and the second lens 660 and then enters the human eyes E. Thus, the human eyes E may see an image composed of polarized light (in FIG. 4, the dashed line with an arrow represents the propagation path of the light emitted by the light-emitting substrate 1100).

It will be understood that the type of display apparatus 1000 provided in the embodiments of the present disclosure is not limited to the liquid crystal display apparatus, the direct display apparatus and the 3D display apparatus, and any other suitable type of display apparatus may be considered as long as a same technical concept is adopted, and the embodiments of the present disclosure will not list them one by one.

Referring to FIGS. 4 and 5, the light-emitting substrate 1100 may include a substrate 100, a plurality of light-emitting elements 200 located on the substrate 100 and a cover plate 300.

The substrate 100 has a first surface 101 (i.e., the upper surface of the substrate 100 in FIG. 5), and the plurality of light-emitting elements 200 are disposed on the first surface 101 of the substrate 100. The light-emitting substrate 1100 further includes a driving circuit layer located on the substrate 100. In other words, the substrate 100 includes a driving circuit layer, and the driving circuit layer is configured to be electrically connected to the light-emitting elements 200 and used to provide a driving signal (e.g., a driving current or a driving voltage) to the light-emitting elements 200, so as to drive the light-emitting elements 200 to emit light and display a corresponding gray scale according to the driving signal.

In some embodiments, the light-emitting element 200 may be a light-emitting diode (LED) light-emitting element. For example, the light-emitting element 200 may be a mini light-emitting diode (Mini-LED) within a range of 100 μm to 500 μm, inclusive; alternatively, the light-emitting element 200 may be a micro light-emitting diode (Micro-LED) with a size less than 100 μm; alternatively, the light-emitting element 200 may be an LED with a large size (e.g., a size greater than 500 μm). In a case where the light-emitting element 200 is the Mini-LED or the Micro-LED, the light-emitting element 200 may also be referred to as an LED chip or a light-emitting chip.

In some embodiments, a size of the light-emitting element 200 is less than or equal to 300 μm. As shown in FIG. 4, in a first direction X, a gap between two adjacent light-emitting elements 200 may be D1, and D1 is within a range of 50 μm to 1000 μm, inclusive. In a second direction Y, a gap between two adjacent light-emitting elements 200 may be D2, and D2 is within a range of 50 μm to 1000 μm, inclusive.

In some embodiments, the size of the light-emitting element 200 is less than or equal to 50 μm. That is to say, a size of an orthogonal projection of the light-emitting element 200 on the first surface 101 is less than 50 μm. For example, the size of the orthogonal projection of the light-emitting element 200 on the first surface 101 may be 50 μm, 45 μm, 40 μm or other suitable sizes, and the embodiments of the present disclosure will not list this one by one.

Referring to FIG. 4, in the first direction X, the gap between two adjacent light-emitting elements 200 may be D1, and D1 is within a range of 6 μm to 300 μm, inclusive. For example, a value of D1 may be 6 μm, 50 μm, 200 μm, or 300 μm, and the embodiments of the present disclosure will not list this one by one. And/or, in the second direction Y, the gap between two adjacent light-emitting elements 200 may be D2, and D2 is within a range of 6 μm to 300 μm, inclusive. A value of D2 may be 6 μm, 100 μm, 250 μm, or 300 μm, and the embodiments of the present disclosure will not list this one by one. The values of D1 and D2 may be equal or different. For example, the value of D1 may be the same as the value of D2.

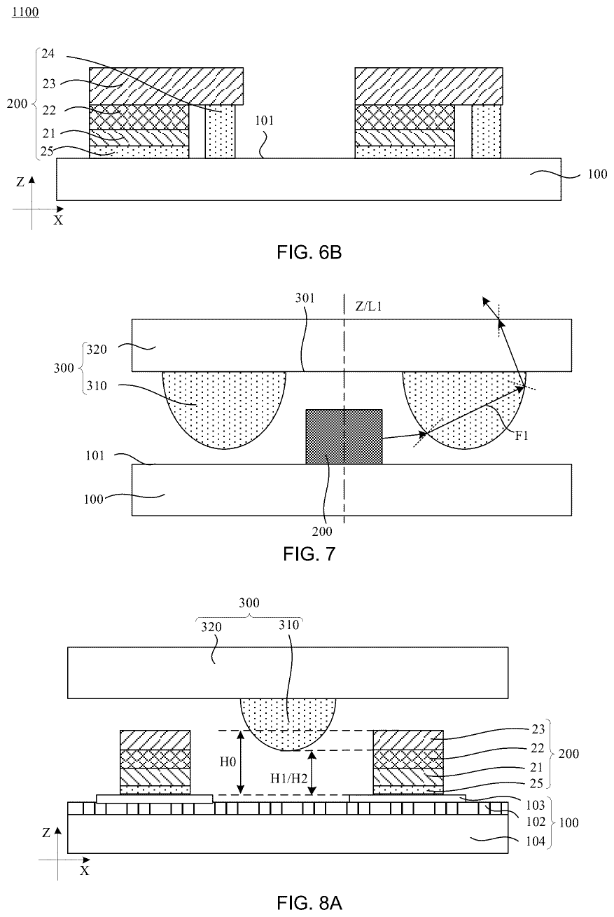

For example, referring to FIGS. 6A and 6B, in a case where the light-emitting element 200 is the Micro-LED, the light-emitting element 200 may include a first semiconductor layer 21, a light-emitting layer 22, and a second semiconductor layer 23 that are sequentially stacked in a direction away from the substrate 100.

The first semiconductor layer 21 may be made of a P-type semiconductor material, and correspondingly, the second semiconductor layer 23 may be made of an N-type semiconductor material. Alternatively, the first semiconductor layer 21 may be made of the N-type semiconductor material, and correspondingly, the second semiconductor layer 23 may be made of the P-type semiconductor material. The intrinsic semiconductor materials of the P-type semiconductor material and the N-type semiconductor material may be any one of gallium nitride (GaN), gallium phosphide (GaP), aluminum gallium arsenide (AlGaAs) and aluminum gallium indium phosphide (AlGaInP). P-type doping or N-type doping is performed on the intrinsic semiconductor material, so that the corresponding P-type semiconductor material and N-type semiconductor material are obtained. The light-emitting layer 22 may be a multiple quantum well (MQW) layer.

In some embodiments, as shown in FIG. 6B, the light-emitting element 200 may further include a first electrode 24 located on a side of the second semiconductor layer 23 proximate to the substrate 100. The first electrode 24 is connected to the second semiconductor layer 23 and the substrate 100, and is used to connect the substrate 100 with the second semiconductor layer 23, so as to apply a voltage signal to the second semiconductor layer 23.

For example, as shown in FIGS. 6A and 6B, the light-emitting element 200 further includes a second electrode 25, and the second electrode 25 is located on a side of the first semiconductor layer 21 proximate to the substrate 100. The second electrode 25 is connected to the first semiconductor layer 21, and the second electrode 25 is connected to the substrate 100. The second electrode 25 is used to transmit an electrical signal to the first semiconductor layer 21. For example, the second electrode 25 is used to apply a voltage to the first semiconductor layer 21. The second electrode 25 may be made of a metal material. For example, the second electrode 25 may be a metal laminate structure. The metal laminate structure may include a gold (Au) layer, a nickel (Ni) layer, an aluminum (Al) layer and a titanium (Ti) layer stacked in a direction away from a driving backplane (e.g., the substrate 100); or, the metal laminate structure includes a gold layer, a platinum layer and a chromium layer stacked in the direction away from the driving backplane. The second electrode 25 may also play a light-reflecting role to reflect the light incident on the second electrode 25 and make the light exit in the direction away from the substrate 100, which is conducive to increasing the light-emitting efficiency of the light-emitting element 200.

It will be noted that the structures of the light-emitting elements 200 are only two specific examples and do not constitute a limitation to the present disclosure, and the light-emitting elements 200 may be light-emitting elements of any other structure.

In the related art, at least part of the light emitted by the light-emitting element 200 scatters in all directions. The light scattering in all directions is not only not conducive to improving the light-emitting brightness of the light-emitting substrate in a front view direction (i.e., a direction perpendicular to the substrate and away from the substrate), in addition, but also may cause light of adjacent light-emitting elements to interfere with each other.

In order to solve the above technical problems, for the light-emitting substrate 1100 provided in the embodiments of the present disclosure, referring to FIGS. 4 and 5, the light-emitting substrate 1100 further includes a cover plate 300.

The cover plate 300 includes a plurality of lens structures 310 protruding toward the substrate 100. Orthogonal projections of centers 311 of the lens structures 310 on the substrate 100 are located outside orthogonal projections of the light-emitting elements 200 on the substrate 100. That is to say, the orthogonal projections of the centers 311 of the lens structures 310 on the substrate 100 do not overlap with the orthogonal projections of the light-emitting elements 200 on the substrate 100. An orthogonal projection of at least one of the lens structures 310 on the substrate 100 is located between the orthogonal projections of adjacent light-emitting elements 200 on substrate 100. In this way, in one aspect, an overlapping area between the light-emitting element 200 and the lens structure 310 may be reduced, and the light emitted by the light-emitting element 200 to the lens structure 310 in a direction perpendicular to the substrate 100 may be reduced, thereby reducing the shielding of the lens structure 310 on the light emitted by the light-emitting element 200 in the front view direction. In another aspect, at least part of the light emitted by the light-emitting element 200 and scattering in all directions may be incident into the lens structure 310. The lens structure 310 is configured to converge the light incident into the lens structure 310. That is to say, the lens structure 310 is a lens structure 310 that may play a light-gathering function. On this basis, at least part of the light emitted by the light-emitting element 200 and scattering in all directions that is incident into the lens structure 310 may be converged in the lens structure 310, thereby improving the light-emitting brightness of the light-emitting substrate 1100 in the front view direction.

In some embodiments, referring to FIGS. 4 and 5, the light-emitting substrate 1100 further includes a sealing portion 400 and a filling portion 500. The sealing portion 400, the substrate 100, and the cover plate 300 together form a closed space surrounding the filling portion 500. That is to say, the sealing portion 400, the substrate 100 and the cover plate 300 form a closed space, and the filling portion 500 is filled in the closed space.

For example, the sealing portion 400 is disposed on the first surface 101 of the substrate 100 and surrounds the plurality of light-emitting elements 200. For example, the sealing portion 400 may extend along a circumferential edge of the substrate 100, and the sealing portion 400 may form a closed annular structure. The cover plate 300 is disposed on a side of the plurality of light-emitting elements 200 and the sealing portion 400 away from the substrate 100 and is connected to the sealing portion 400. The cover plate 300, the substrate 100 and the sealing portion 400 form the closed space.

For example, the sealing portion 400 may not only bond and fix the cover plate 300 to the substrate 100, but also be combined with the cover plate 300 and the substrate 100 to form the closed space.

In some embodiments, the sealing portion 400 may be made of a material with a water vapor transmission rate (WVTR) less than 10⁻², so as to enhance the performance of the sealing portion 400 to isolate water vapor, thereby enhancing the protection performance of the substrate 100 and the light-emitting elements 200.

A refractive index of the filling portion 500 is less than a refractive index of the lens structure 310, or in other words, the refractive index of the lens structure 310 is greater than the refractive index of the filling portion 500.

In some embodiments, the filling portion 500 may be gas. In this way, a gas layer with a low refractive index may be formed around the light-emitting elements 200. A refractive index of the gas layer is less than the refractive index of the lens structure 310, so that light may be refracted when the light is incident from the gas layer into the lens structure 310.

The gas may be, for example, an inert gas, or any other gas that does not react with the substrate 100, the light-emitting elements 200, the sealing portion 400, the cover plate 300 and the lens structures 310 (during the fabrication and use of the light-emitting substrate). For example, the filling portion 500 may include nitrogen, nitrogen has the advantages of low cost, high safety, and low refractive index. Of course, the type of gas filled in the filling portion 500 is not limited thereto, and any suitable single gas or mixed gas may be considered.

In some embodiments, in a case where the filling portion 500 is gas, the refractive index of the filling portion 500 is close to 1. In this case, the refractive index of the lens structure 310 may be greater than or equal to 1.5. In this way, it is possible to improve the convergence effect of the lens structure 310 on the light incident to the lens structure 310, and it is conducive to reducing a total reflection angle of the lens structure 310, which helps the light to exit from the lens structure 310. For example, the refractive index of the lens structure 310 may be 1.5, 1.6, 1.8, 2.5 or 3. For example, the refractive index of the lens structure 310 may be within a range of 1.5 to 2.0, inclusive. The embodiments of the present disclosure are not limited thereto, and any other suitable refractive index may also be considered for the lens structure 310.

For example, referring to FIG. 7, in a case where at least part of the light emitted by the light-emitting element 200 is incident from the filling portion 500 into the lens structure 310, the light is refracted on a surface of the lens structure 310. Moreover, compared with the light before refraction, an included angle between the refracted light and the front view direction (i.e., the direction perpendicular to the first surface 101) L1 is reduced. A part light F1 of the refracted light is incident to a surface of the lens structure 310 away from the light-emitting element 200, and at least part of the part light F1 may be totally reflected on the surface of the lens structure 310 away from the light-emitting element 200. Then the light is incident to a surface of the lens structure 310 in contact with the cover plate 300, and exits from the surface of the lens structure 310 in contact with the cover plate 300. Compared with a direction in which the part light F1 exits from the light-emitting element 200, an included angle between a propagation direction of the light refracted and total reflected by the lens structure 310 and the front view direction L1 is reduced, which is conducive to increasing the light-emitting brightness of the light-emitting elements 200 in the front view direction. Of course, there are also other parts of the light, whose included angle with the front view direction L1 is reduced after passing through the lens structure 310, which will not be repeated in detail in the embodiments of the present disclosure. In the embodiments of the present disclosure, by providing the lens structures 310, it is conducive to increasing the amount of light exiting from the light-emitting elements 200 in the front view direction L1, thereby increasing the light-emitting brightness of the light-emitting substrate 1100 in the front view direction.

In some embodiments, referring to FIGS. 5 and 7, a dimension of the sealing portion 400 in a direction Z (i.e., the vertical direction in FIG. 5, hereinafter referred to as a fourth direction Z) perpendicular to the first surface 101 may be greater than or equal to a dimension of the light-emitting element 200 in the fourth direction Z. For example, the dimension of the sealing portion 400 in the fourth direction Z is greater than the dimension of the light-emitting element 200 in the fourth direction Z, so that there is a gap between an end portion of the light-emitting element 200 proximate to the cover plate 300 and the cover plate 300. This may reduce the risk of collision and extrusion between the cover plate 300 and the light-emitting elements 200, and the risk of damage to the light-emitting elements 200.

In some embodiments, the dimension of the light-emitting element 200 in the direction (i.e., the fourth direction Z) perpendicular to the first surface 101 is within a range of 5 μm to 20 μm, inclusive. For example, the dimension of the light-emitting element 200 in the direction perpendicular to the first surface 101 may be 5 μm, 10 μm, 15 μm or 20 μm, which will not be listed one by one in the embodiments of the present disclosure.

The dimension of the sealing portion 400 in the direction (i.e., the fourth direction Z) perpendicular to the first surface 101 is within a range of 6 μm to 140 μm, inclusive, and the dimension of the sealing portion 400 in the fourth direction Z is greater than the dimension of the light-emitting element 200 in the fourth direction Z. In this way, it is possible to prevent the light-emitting elements 200 and the cover plate 300 from being squeezed with each other, and prevent the light-emitting elements 200 and the cover plate 300 from being damaged during the connection between the cover plate 300 and the sealing portion 400, thereby improving the reliability of the light-emitting elements 200. For example, the dimension of the sealing portion 400 in the direction (i.e., the fourth direction Z) perpendicular to the first surface 101 is 6 μm, 20 μm, 50 μm, 100 μm or 140 μm, which will not be listed one by one in the embodiments of the present disclosure.

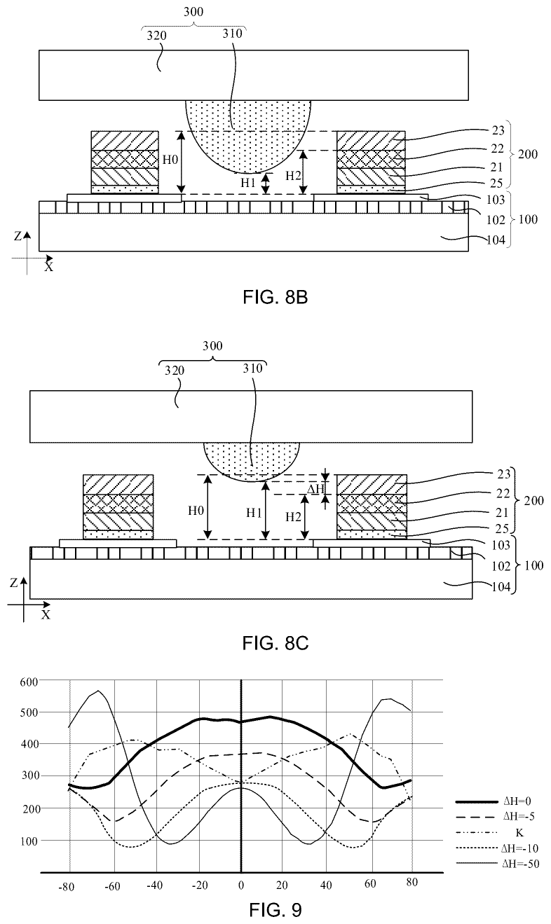

In some embodiments, referring to FIGS. 8A to 8C, in a thickness direction (i.e., the direction perpendicular to the first surface 101 or the fourth direction Z) of the light-emitting element 200, a minimum distance H1 from the lens structure 310 to the substrate 100 is less than or equal to a distance H0 from an end of the light-emitting element 200 away from the substrate 100 to the substrate 100. The distance H0 from the end of the light-emitting element 200 away from the substrate 100 to the substrate 100 is a thickness of the light-emitting element 200. In other words, the minimum distance H1 from the lens structure 310 to the substrate 100 is less than or equal to the thickness HO of the light-emitting element 200. In this case, the center of the orthogonal projection of the lens structure 310 on the substrate 100 is located between adjacent light-emitting elements 200, which may avoid interference (e.g., mutual collision) between the lens structure 310 and the light-emitting element 200, and may also reduce the overall thickness of the light-emitting substrate 1100.

In some embodiments, referring to FIGS. 8A to 8C, the substrate 100 may include a substrate layer 104, a circuit layer 102 and a metal pad layer 103 disposed on the circuit layer 102. The circuit layer 102 (e.g., the driving circuit layer) is used for the arrangement of driving circuits and signal traces. The metal pad layer 103 is disposed on a side of the circuit layer 102 proximate to the light-emitting elements 200 and is used to connect to the light-emitting elements 200.

It will be noted that the distance H0 from the end of the light-emitting element 200 away from the substrate 100 to the substrate 100 is the thickness of the light-emitting element 200, and the thickness here refers to the overall thickness of the light-emitting element 200. In FIGS. 6A, 6B and 8A to 8C, only an end of the second semiconductor layer 23 away from the substrate 100 is shown as the end of the light-emitting element 200 away from the substrate 100. In fact, there may also be other film layers (e.g., the growth base or color conversion layer of the LED) on the end of the second semiconductor layer 23 away from the substrate 100. Therefore, a highest point of the solid film layers consecutively arranged on the second electrode 25 of the light-emitting element 200 should be considered as the end of the light-emitting element 200 away from the substrate 100.

Referring to FIGS. 8A to 8C, the minimum distance H1 from the lens structure 310 to the substrate 100 refers to a distance from the lens structure 310 to an upper surface of the metal pad layer 103, so that comparison starting points of H1 and H0 are on a same horizontal plane.

In some embodiments, referring to FIG. 8A, in the thickness direction (i.e., the fourth direction Z) of the light-emitting element 200, the minimum distance H1 from the lens structure 310 to the substrate 100 is equal to a distance H2 from a surface of the light-emitting layer 22 away from the substrate 100 to the substrate 100. In other words, an end portion (i.e., the lower end) of the lens structure 310 proximate to the first surface 101 is flush with an upper surface of the light-emitting layer 22. Alternatively, referring to FIG. 8B, in the thickness direction (i.e., the fourth direction Z) of the light-emitting element 200, the minimum distance H1 from the lens structure 310 to the substrate 100 is less than the distance H2 from the surface of the light-emitting layer 22 away from the substrate 100 to the substrate 100. That is to say, the end portion of the lens structure 310 proximate to the first surface 101 is closer to the first surface 101 than the upper surface of the light-emitting layer 22. Alternatively, referring to FIG. 8C, in the thickness direction (i.e., the fourth direction Z) of the light-emitting element 200, the minimum distance H1 from the lens structure 310 to the substrate 100 is greater than the distance H2 from the surface (i.e., the upper surface) of the light-emitting layer 22 away from the substrate 100 to the substrate 100, and a difference ΔH between the minimum distance H1 from the lens structure 310 to the substrate 100 and the distance from the surface of the light-emitting layer 22 away from the substrate 100 to the substrate 100 is less than or equal to 10 μm. The three arrangements of the lens structure 310 may greatly increase the amount of light received by the lens structure 310, thereby increasing the light converged by the lens structure 310, which is conducive to increasing the brightness of the light-emitting element 200 in the front view direction.

Referring to FIG. 9, FIG. 9 is a graph showing simulation results of a light intensity of the light-emitting element 200 at different viewing angles in a case where the difference ΔH between the minimum distance H1 from the lens structure 310 to the substrate 100 and the distance from the surface of the light-emitting layer 22 away from the substrate 100 to the substrate 100 takes different values. The horizontal coordinate is the viewing angle (i.e., the included angle with the fourth direction Z) of the light-emitting element 200, and the vertical coordinate is the intensity (i.e., brightness) of the light; ΔH refers to the distance H2 from the surface of the light-emitting layer 22 away from the substrate 100 to the substrate 100, minus the minimum distance H1 from the lens structure 310 to the substrate 100. For example, “ΔH=0” means that H1 is equal to H2 (as shown in FIG. 8A), and “ΔH<0” (i.e., ΔH is a negative value) means that H1 is greater than H2 (i.e., H1>H2 ) (as shown in FIG. 8C). “K” refers to a control group, which is a curve showing the light intensity of the light-emitting element 200 at different viewing angles in a case where no lens structure 310 is provided. In the simulation corresponding to FIG. 9, the orthogonal projection of the light-emitting element 200 on the substrate is in a shape of a rectangle with a length of 40 μm and a width of 20 μm, and the thickness of the light-emitting element 200 is 7 μm (considering only the thicknesses of the first semiconductor layer, the multiple quantum well layer, and the second semiconductor layer); the lens structures are disposed in front, rear, left, and right of the light-emitting element (e.g., as shown in FIG. 4, the lens structures 310 may be disposed on two sides of the light-emitting 200 in the first direction X and on two sides of the light-emitting 200 in the second direction Y), and the orthogonal projections of the lens structures on the substrate each are in a shape of a circle with a diameter of 42 μm, a curvature of the lens structures 310 is 0.05; a distance between the centers of the lens structures 310 oppositely disposed in an extending direction of a short side of the light-emitting element 200 is 70 μm, and a distance between the centers of the lens structures 310 oppositely disposed in an extending direction of a long side of the light-emitting element 200 is 90 μm, the refractive index of the lens structures is 1.6, a center of the light-emitting element 200 is located between the centers of the lens structures oppositely disposed in the extending direction of the short side of the light-emitting element, and the center of the light-emitting element 200 is located between the centers of the lens structures oppositely disposed in the extending direction of the long side of the light-emitting element.

By comparing the multiple curves in FIG. 9, it may be seen that in a case where ΔH is equal to 0 (i.e., ΔH=0) or ΔH is equal to −5 (i.e., ΔH=−5), the luminous intensity of the light-emitting element 200 in the front view direction is obviously enhanced, and the lens structure 310 has a good constriction effect (i.e., the convergence effect) on the light emitted by the light-emitting element 200, which is conducive to improving the light-emitting brightness of the light-emitting substrate 1100 in the front view direction. In a case where ΔH is equal to −10 (i.e., ΔH=−10), the luminous intensity of the light-emitting element 200 is relatively concentrated within a viewing angle range of −40 to 40, and the lens structure 310 may achieve a certain convergence effect. In a case where ΔH is further reduced, for example, in a case where ΔH is equal to −50 (i.e., ΔH=−50), the lens structure 310 cannot enhance the luminous intensity of the light-emitting element 200 in the front view direction.

In some embodiments, as shown in FIG. 5, there is a gap between the end (i.e., the lower end) of the lens structure 310 proximate to the first surface 101 and the first surface 101. In this way, it is possible to prevent the lens structures 310 from being in contact with the substrate 100 during the connection between the cover plate 300 and the sealing portion 400, and avoid mutual squeezing between the substrate 100 and the lens structures 310, thereby reducing the risk of damage to the lens structures 310 and/or the substrate 100.

In some embodiments, referring to FIGS. 5 and 7, the cover plate 300 further includes an extension portion 320 extending in a plane extending parallel to the substrate 100. The extension portion 320 is located on a side of the lens structures 310 away from the substrate 100, and the extension portion 320 is connected to the lens structures 310. In other words, the plurality of lens structures 310 may be disposed on the extension portion 320, and the extension portion 320 provides a carrier for the plurality of lens structures 310, thereby improving the stability of the cover plate 300.

In some embodiments, the extension portion 320 and the plurality of lens structures 310 may be a one-piece structure. In this case, the extension portion 320 and the plurality of lens structures 310 include a same material. For example, materials of the lens structures 310 and the extension portion 320 may both include at least one of transparent glass and transparent resin.

In some embodiments, the plurality of lens structures 310 may also be independent structures disposed on the extension portion 320. In this case, the extension portion 320 and the plurality of lens structures 310 may include a same material, or the extension portion 320 and the plurality of lens structures 310 may include different materials. The material of the lens structure 310 includes at least one of transparent glass and transparent resin; and/or, the material of the extension portion 320 includes at least one of transparent glass and transparent resin. For example, the extension portion 320 and the plurality of lens structures 310 include a same material, and both the extension portion 320 and the plurality of lens structures 310 include transparent resin. For example, the extension portion 320 and the plurality of lens structures 310 include different materials, and the material of the extension portion 320 includes transparent glass, and the material of the lens structure 310 includes transparent resin.

For example, in a case where the cover plate 300 includes the extension portion 320, as shown in FIGS. 5 and 7, a surface of the extension portion 320 proximate to the first surface 101 is a second surface 301, and at least a portion of the second surface 301 is opposite to the light-emitting elements 200. In this way, the light emitted by the light-emitting elements 200 in the front view direction (i.e., the fourth direction) may be directly incident on the extension portion 320 without passing through the lens structures 310. This is conducive to reducing the loss of light when the light passes through the lens structures 310.

In some embodiments, referring to FIG. 5, a surface of a region of the cover plate between adjacent lens structures 310 facing the substrate 100 is conformal with an extending surface (e.g., the first surface 101) of the substrate 100. That is to say, the first surface 101 and the second surface 301 that are opposite to each other have a same shape. In this way, it is conducive to forming a closed space with uniform thickness between the substrate 100 and the cover plate 300 (i.e., between the first surface 101 and the second surface 301), thereby improving the light-emitting uniformity of the light-emitting substrate 1100.

In some embodiments, as shown in FIG. 5, the surface of the region of the cover plate between adjacent lens structures 310 facing the substrate is a plane, and the first surface 101 of the substrate 100 proximate to the cover plate 300 is a plane.

In some embodiments, referring to FIGS. 5 and 7, the lens structure 310 has an area of a section that decreases in a direction (e.g., from top to bottom) towards the substrate 100. An extending direction of the section is parallel to the extending direction of the substrate opposite to the lens structure, that is, the horizontal section in FIGS. 5 and 7. In other words, in a direction from top to bottom in FIGS. 5 and 7, an area of the horizontal sectional of the lens structure 310 decreases. This is conducive to increasing the included angle between a surface of the lens structure 310 proximate to the light-emitting element 200 and the front view direction, so as to change an incident angle of the light incident to the lens structure 310, which is conducive to enhancing the convergence (e.g., constriction) effect of the lens structure 310 on the light, and thereby enhancing the light-emitting brightness of the light-emitting substrate 1100 in the front view direction.

In some embodiments, as shown in FIGS. 4 and 7, the orthogonal projection of the lens structure 310 on the substrate 100 is in a shape of a circle, and at least part of a surface of the lens structure 310 in contact with the filling portion 500 is a curved surface. That is to say, except for the surface in contact with the extension portion 320, at least part of the other surfaces of the lens structure 310 are curved surfaces. For example, the surfaces of the lens structure 310 in contact with the filling portion 500 are all curved surfaces. For example, the lens structure 310 may form a spherical structure or a structure similar to a sphere. For example, the lens structure 310 may be a spherical structure. In this case, the surface of the lens structure 310 proximate to the substrate 100 may be a spherical surface.

In some embodiments, the surfaces of the lens structure 310 in contact with the filling portion 500 are all a curved surface, and the curvature of the curved surface is less than 0.1. For example, the curvature of the curved surface may vary with different positions on the transmission. For example, the curved surface may have a constant curvature. For example, the curvature may be 0.02, 0.05, 0.075, or 0.1, which is not listed one by one in the embodiments of the present disclosure.

In some embodiments, the surfaces of the lens structure 310 in contact with the filling portion 500 are all a curved surface, and the curvature of the curved surface is within a range of 0.05 to 0.1, inclusive. For example, the curvature of the curved surface may vary with different positions on the transmission. For example, the curved surface may have a constant curvature. For example, the curvature may be 0.05, 0.06, 0.07, 0.08, 0.09, or 0.1, which is not listed one by one in the embodiments of the present disclosure.

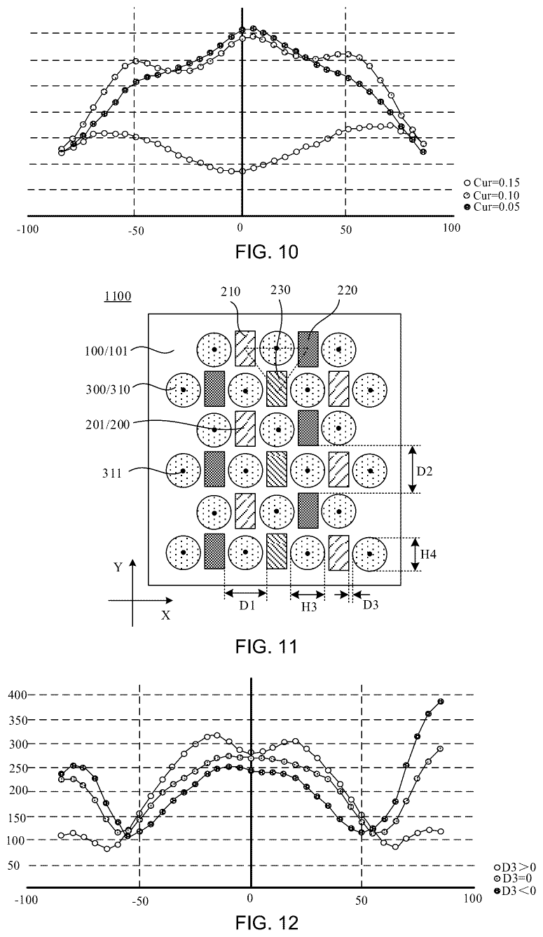

Referring to FIG. 10, FIG. 10 is a graph showing the light intensity of the light-emitting substrate (e.g., the light-emitting element 200) at different viewing angles in a case of different curvatures (Cur) of the lens structure 310. In FIG. 10, the horizontal coordinate is a viewing angle (i.e., the included angle with the fourth direction Z) of the light-emitting element 200, and the vertical coordinate is the intensity (i.e., brightness) of the light. Moreover, FIG. 10 exemplarily shows curves of the light intensity of the light-emitting substrate at different viewing angles in a case of only three curvatures (i.e., 0.05, 0.1 and 0.15). It may be seen from FIG. 10 that in a case where the curvature of the surface of the lens structure 310 is 0.05 or 0.1, the luminous intensity of the light-emitting substrate in the front view direction is obviously enhanced, and the lens structure 310 has a good constriction effect (i.e., the convergence effect) on the light emitted by the light-emitting element 200, which is conducive to improving the light-emitting brightness of the light-emitting substrate 1100 in the front view direction. In the simulation corresponding to FIG. 10, the orthogonal projection of the light-emitting element 200 on the substrate is in a shape of a rectangle with a length of 40 μm and a width of 20 μm, and the thickness of the light-emitting element 200 is 7 μm (considering only the thicknesses of the first semiconductor layer, the multiple quantum well layer, and the second semiconductor layer); the lens structures are disposed in front, rear, left, and right of the light-emitting element 200, and the orthogonal projections of the lens structures on the substrate each are in a shape of a circle with a diameter of 42 μm; a distance between the centers of the lens structures oppositely disposed in an extending direction of a short side of the light-emitting element is 70 μm, and a distance between the centers of the lens structures oppositely disposed in an extending direction of a long side of the light-emitting element is 90 μm, the refractive index of the lens structures is 1.6, the center of the light-emitting element 200 is located between the centers of the lens structures oppositely disposed in the extending direction of the short side of the light-emitting element, and the center of the light-emitting element 200 is located between the centers of the lens structures oppositely disposed in the extending direction of the long side of the light-emitting element.

The curvature of the curved surface of the lens structure 310 may be constant or variable. That is to say, the curvatures of the curved surface at different positions may be completely same, or the curvatures of the curved surface at different positions may all be different.

In some embodiments, referring to FIG. 11, the plurality of light-emitting elements 200 include a plurality of light-emitting element groups 201, one light-emitting element group 201 includes at least one light-emitting element 200. The plurality of light-emitting element groups 201 are arranged in multiple rows and multiple columns, and two adjacent light-emitting element groups 201 respectively belonging to two adjacent rows are disposed in a staggered manner in the first direction X, and two adjacent light-emitting element groups 201 respectively belonging to two adjacent columns are disposed in a staggered manner in the second direction Y. This is conducive to increasing a gap between adjacent light-emitting element groups 201 and increasing a space between adjacent light-emitting element groups 201. For example, a space of a region enclosed by the four closest light-emitting element groups 201 in two adjacent rows and two adjacent columns may be increased, which is conducive to providing the lens structure 310 in the space, increasing the size of the lens structure 310, and reducing the risk of interference between the lens structure 310 and the light-emitting element(s) 200 included in the light-emitting element group 201.

The first direction X is a row direction in which the plurality of light-emitting element groups 201 are arranged, and the second direction Y is a column direction in which the plurality of light-emitting element groups 201 are arranged. The first direction X intersects with the second direction Y. For example, the first direction X and the second direction Y are perpendicular to each other.

In some embodiments, referring to FIG. 11, the orthogonal projections of the plurality of lens structures 310 on the substrate 100 do not overlap with the orthogonal projections of the plurality of light-emitting elements 200 on the substrate 100. That is to say, the orthogonal projections of all lens structures 310 on the substrate 100 are all located outside the range of the light-emitting elements 200. In this way, it is possible to greatly reduce the shielding of the lens structure 310 on the light of the light-emitting element 200 in the front view direction, and help the large-angle light emitted by the light-emitting element 200 to enter the lens structure 310, and enhance the convergence effect of the lens structure 310 on the large-angle light emitted by the light-emitting element 200.

In some embodiments, referring to FIG. 11, the orthogonal projection of the lens structure 310 on the substrate 100 is located between adjacent light-emitting element groups 201 and has a gap D3 from the light-emitting element group 201. By increasing the distance between the lens structure 310 and the light-emitting element group 201 (e.g., the light-emitting element 200), it is conducive to improving the convergence effect of the lens structure 310 on the light emitted by the light-emitting element 200, and it may also reduce the shielding of the lens structure 310 on the light emitted by the light-emitting element 200 in the front view direction, thereby improving the light-emitting brightness of the light-emitting substrate 1100 in the front view direction.

In some embodiments, as shown in FIG. 11, one light-emitting element group 201 includes one light-emitting element 200. The plurality of light-emitting elements 200 include a plurality of first light-emitting elements 210, a plurality of second light-emitting elements 220, and a plurality of third light-emitting elements 230. One of the first light-emitting elements 210, the second light-emitting elements 220, and the third light-emitting elements 230 is configured to emit red light, another of the first light-emitting elements 210, the second light-emitting elements 220, and the third light-emitting elements 230 is configured to emit green light, and yet another of the first light-emitting elements 210, the second light-emitting elements 220, and the third light-emitting elements 230 is configured to emit blue light. In this way, the combination of the first light-emitting element 210, the second light-emitting element 220 and the third light-emitting element 230 may form lights of different colors by superposition, so that the full-color display of the light-emitting substrate 1100 may be achieved.

For example, the first light-emitting element 210 is configured to emit red light, one of the second light-emitting element 220 and the third light-emitting element 230 is configured to emit green light, and another of the second light-emitting element 220 and the third light-emitting element 230 is configured to emit blue light. For example, the second light-emitting element 220 is configured to emit green light, and the third light-emitting element 230 is configured to emit blue light.

With continued reference to FIG. 11, a line connecting centers of the orthogonal projections of one first light-emitting element 210, one second light-emitting element 220, and one third light-emitting element 230 that are closest to each other on the substrate 100 is in a shape of a triangle. That is to say, the plurality of light-emitting elements 200 are arranged in a Delta arrangement. That is to say, two adjacent light-emitting elements 200 respectively belonging to two adjacent rows are disposed in a staggered manner in the row direction (i.e., the first direction X) in which the light-emitting element groups 201 are arranged, and two adjacent light-emitting elements 200 respectively belonging to two adjacent columns are disposed in a staggered manner in the column direction (i.e., the second direction Y) in which the light-emitting element groups 201 are arranged. In this way, a gap between adjacent light-emitting elements 200 may be greatly increased, thereby improving the arrangement space of the lens structures 310. That is to say, the plurality of light-emitting elements 200 are arranged in the Delta arrangement, which may increase the gaps between adjacent light-emitting elements 200 in the first direction X and the second direction Y, and help the lens structure 310 to be disposed between adjacent light-emitting elements 200.

In some embodiments, referring to FIG. 11, a maximum length H3 of the orthogonal projection of the lens structure 310 on the substrate 100 in the first direction X is less than or equal to the distance D1 (i.e., the gap D1) between two light-emitting elements 200 adjacent to the lens structure 310 in the first direction X; and/or, a maximum length H4 of the orthogonal projection of the lens structure 310 on the substrate 100 in the second direction Y is less than or equal to the distance D2 (i.e., the gap D2) between two light-emitting elements 200 adjacent to the lens structure 310 in the second direction Y. In this way, the lens structure 310 may be completely disposed in the gap between adjacent light-emitting elements 200, or in other words, the orthogonal projections of the lens structures 310 on the substrate 100 do not overlap with the light-emitting elements 200. This is conducive to increasing the distance between the lens structure 310 and the light-emitting element 200, and improving the convergence effect of the lens structure 310 on light. Moreover, it may also reduce the shielding of the lens structure 310 on the light emitted by the light-emitting element 200 in the front view direction, thereby improving the light-emitting brightness of the light-emitting substrate 1100 in the front view direction.

For example, the orthogonal projection of the lens structure 310 on the substrate 100 is located between adjacent light-emitting elements 200 and has the gap D3 from the light-emitting element 200. In this way, it is possible to increase the distance between the lens structure 310 and the light-emitting element 200, and is conducive to improving the convergence effect of the lens structure 310 on light, and is also possible to reduce the shielding of the lens structure 310 on the light emitted by the light-emitting element 200 in the front view direction, thereby improving the light-emitting brightness of the light-emitting substrate 1100 in the front view direction.

In some embodiments, as shown in FIG. 11, in a case where the light-emitting elements 200 are arranged in the Delta arrangement, a gap between adjacent light-emitting elements 200 may be within a range of 6 μm to 300 μm, inclusive. That is to say, the gap D1 between two adjacent light-emitting elements 200 in the first direction X is within a range of 6 μm to 300 μm, inclusive, and the gap D2 between two adjacent light-emitting elements 200 in the second direction Y is also within a range of 6 μm to 300 μm, inclusive. For example, the gap D1 between two adjacent light-emitting elements 200 in the first direction X may be 6 μm, 10 μm, 50 μm, 150 μm or 300 μm, and the gap D2 between two adjacent light-emitting elements 200 in the second direction Y may be 6 μm, 30 μm, 100 μm, 200 μm or 300 μm. The gap D1 between two adjacent light-emitting elements 200 in the first direction X may be equal to or different from the gap D2 between two adjacent light-emitting elements 200 in the second direction Y.

The dimension H3 (i.e., the maximum length H3) of the orthogonal projection of the lens structure 310 on the substrate 100 in the first direction X may be within a range of 4 μm to 260 μm, inclusive, and the dimension H4 (i.e., the maximum length H4) of the orthogonal projection of the lens structure 310 on the substrate 100 in the second direction Y may be within a range of 4 μm to 260 μm, inclusive. In this way, the orthogonal projection of the lens structure 310 on the substrate 100 may be completely located between adjacent light-emitting elements 200 and not overlap with the light-emitting elements 200. For example, the dimension H3 of the orthogonal projection of the lens structure 310 on the substrate 100 in the first direction X may be 4 μm, 15 μm, 60 μm, 200 μm or 260 μm; the dimension H4 of the orthogonal projection of the lens structure 310 on the substrate 100 in the second direction Y may be 4 μm, 15 μm, 60 μm, 200 μm or 260 μm, which are not listed one by one herein. The gap D1 between two adjacent light-emitting elements 200 in the first direction X is greater than the dimension of the lens structure 310 in the first direction X, and the gap D2 between two adjacent light-emitting elements 200 in the second direction Y is greater than the dimension of the lens structure 310 in the second direction Y, which is conducive to providing the lens structures 310 in the gaps between the plurality of light-emitting elements 200. Through the arrangement between the light-emitting elements 200 and the lens structures 310, the shielding of the lens structure 310 on the light emitted by the light-emitting element 200 in the front view direction may be greatly reduced, and the gap between the lens structure 310 and the light-emitting element 200 may be greatly increased, which is conducive to improving the convergence effect of the lens structure 310 on the light, thereby improving the light-emitting brightness of the light-emitting substrate 1100 in the front view direction.

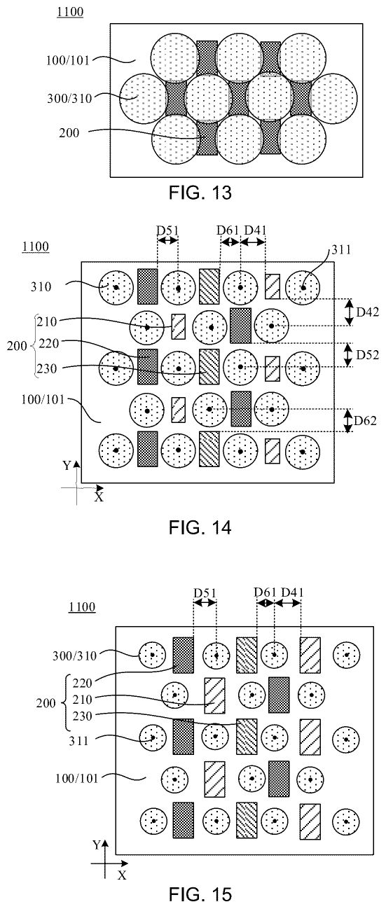

Referring to FIG. 12, FIG. 12 is a graph showing simulation results of the light intensity of the light-emitting substrate 1100 at different viewing angles in a case where the lens structure 310 has different gaps D3 with the light-emitting element 200, and a case where D3 is less than 0 (i.e., D3<0), a case where D3 is greater than 0 (i.e., D3>0) and a case where D3 is equal to 0 (i.e., D3=0) each are tested. “D3<0” means that the orthogonal projection of the lens structure 310 on the first surface 101 partially overlaps with the orthogonal projection of the light-emitting element 200 on the first surface 101 (as shown in FIG. 13). “D3>0” means that, as shown in FIG. 11, there is an gap between the orthogonal projection of the lens structure 310 on the first surface 101 and the orthogonal projection of the light-emitting element 200 on the first surface 101. “D3=0” means that the orthogonal projection of the lens structure 310 on the first surface 101 is tangent to the orthogonal projection of the light-emitting element 200 on the first surface 101 (not shown in the drawings). In the simulation corresponding to FIG. 12, the orthogonal projection of the light-emitting element 200 on the substrate is in a shape of a rectangle with a length of 40 μm and a width of 20 μm, and the thickness of the light-emitting element 200 is 7 μm (considering only the thicknesses of the first semiconductor layer, the multiple quantum well layer, and the second semiconductor layer); the lens structures are disposed in front, rear, left, and right of the light-emitting element 200, and the orthogonal projections of the lens structures on the substrate each are in a shape of a circle with a diameter of 42 μm, the curvature of the lens structures is 0.05; a distance between the centers of the lens structures oppositely disposed in an extending direction of a short side of the light-emitting element is 70 μm, and a distance between the centers of the lens structures oppositely disposed in an extending direction of a long side of the light-emitting element is 90 μm, the refractive index of the lens structures is 1.6, the center of the light-emitting element 200 is located between the centers of the lens structures oppositely disposed in the extending direction of the short side of the light-emitting element, and the center of the light-emitting element 200 is located between the centers of the lens structures oppositely disposed in the extending direction of the long side of the light-emitting element.

As may be seen from FIG. 12, as the gap D3 between the orthogonal projections of the lens structure 310 and the light-emitting element 200 on the first surface 101 increases, the luminous intensity of the light-emitting element 200 within a viewing angle range of −50° to 50° increases. That is to say, as the gap D3 between the orthogonal projections of the lens structure 310 and the light-emitting element 200 on the first surface 101 increases, it is conducive to improving the convergence effect of the lens structure 310 on the light emitted by the light-emitting element 200.

In some embodiments, at least one light-emitting element group may include two light-emitting elements. For example, some light-emitting element groups each include one light-emitting element. For example, one first light-emitting element emitting red light constitutes one light-emitting element group, and one third light-emitting element emitting blue light constitutes one light-emitting element group, and two second light-emitting elements emitting green light constitute one light-emitting element group. No lens structure may be disposed between two or more light-emitting elements included by one light-emitting element group.

In some embodiments, the plurality of light-emitting elements included by the light-emitting substrate may also be light-emitting elements emitting light of a same color. In this case, the display apparatus may be a display apparatus displaying a single color. Alternatively, the display apparatus may further include a color conversion layer. The color conversion layer is disposed on a light-exit side of the light-emitting substrate and configured to convert at least part of the light emitted by the light-emitting substrate into light of other colors, so that multi-color or even full-color display of the display apparatus may be achieved.

Of course, in some other embodiments, referring to FIG. 13, the orthogonal projection of the lens structure 310 on the first surface 101 may also partially overlap with the orthogonal projection of the light-emitting element 200 on the first surface 101. For example, edge region(s) of the orthogonal projection of the lens structure 310 on the first surface 101 proximate to the light-emitting element 200 overlap with the orthogonal projection of the light-emitting element 200 on the first surface 101. In this case, the lens structure 310 may still converge the light emitted by the light-emitting element 200, so as to increase the light-emitting brightness of the light-emitting element 200 in the front view direction.

In some embodiments, referring to FIG. 14, the plurality of light-emitting elements 200 include a plurality of first light-emitting elements 210, a plurality of second light-emitting elements 220, and a plurality of third light-emitting elements 230. The first light-emitting element 210 is configured to emit red light, one of the second light-emitting element 220 and the third light-emitting element 230 is configured to emit green light, and another of the second light-emitting element 220 and the third light-emitting element 230 is configured to emit blue light. For example, the second light-emitting element 220 is configured to emit green light, and the third light-emitting element 230 is configured to emit blue light. In this way, the full-color display of the light-emitting substrate 1100 may be achieved.

With continued reference to FIG. 14, in the first direction X, a distance D41 between the center 311 of the orthogonal projection of the lens structure 310 on the first surface 101 and the first light-emitting element 210 is greater than a distance D51 between the center 311 of the orthogonal projection of the lens structure 310 on the first surface 101 and the second light-emitting element 220, and is greater than a distance D61 between the center 311 of the orthogonal projection of the lens structure 310 on the first surface 101 and the third light-emitting element 230. That is to say, in the orthogonal projections on the first surface 101, in the first direction X, the distance D41 between the center 311 of the lens structure 310 and the first light-emitting element 210 is greater than the distance D51 between the center 311 of the lens structure 310 and the second light-emitting element 220 (i.e., D41>D51), and is greater than the distance D61 between the center 311 of the lens structure 310 and the third light-emitting element 230 (i.e., D41>D61).

In some embodiments, in the second direction Y, a distance D42 between the center 311 of the orthogonal projection of the lens structure 310 on the first surface 101 and the first light-emitting element 210 is greater than a distance D52 between the center 311 of the orthogonal projection of the lens structure 310 on the first surface 101 and the second light-emitting element 220, and is greater than a distance D62 between the center 311 of the orthogonal projection of the lens structure 310 on the first surface 101 and the third light-emitting element 230. That is to say, in the orthogonal projections on the first surface 101, in the second direction Y, the distance D42 between the center 311 of the lens structure 310 and the first light-emitting element 210 is greater than the distance D52 between the center 311 of the lens structure 310 and the second light-emitting element 220 (i.e., D42>D52), and is greater than the distance D62 between the center 311 of the lens structure 310 and the third light-emitting element 230 (i.e., D42>D62).

It is found through research that the light-emitting efficiency of the first light-emitting element 210 emitting red light is less than the light-emitting efficiency of the second light-emitting element 220 and the third light-emitting element 230. By increasing the distance D41 between the first light-emitting element 210 and the center 311 of the lens structure 310 in the first direction X and the distance D42 between the first light-emitting element 210 and the center 311 of the lens structure 310 in the second direction Y, the amount of light emitted by the first light-emitting element 210 into the lens structure 310 may be increased, and the convergence effect of the lens structure 310 on the light emitted by the first light-emitting element 210 may be increased, thereby improving the light-emitting brightness of the first light-emitting element 210 at the front viewing angle. Moreover, it is conducive to balancing the light-emitting uniformity of the first light-emitting element 210, the second light-emitting element 220 and the third light-emitting element 230 in the front view direction.

For example, as shown in FIG. 14, in some embodiments, a size of the first light-emitting element 210 is less than sizes of the second light-emitting element 220 and the third light-emitting element 230, so that the distance D41 between the first light-emitting element 210 and the center 311 of the lens structure 310 in the first direction X and the distance D42 between the first light-emitting element 210 and the center 311 of the lens structure 310 in the second direction Y may be increased.

Alternatively, referring to FIG. 15, in some other embodiments, the size of the first light-emitting element 210 is the same as the sizes of the second light-emitting element 220 and the third light-emitting element 230. In this case, the lens structure 310 located between the first light-emitting element 210 and the third light-emitting element 230 is disposed proximate to the third light-emitting element 230; the lens structure 310 located between the first light-emitting element 210 and the second light-emitting element 220 is disposed proximate to the second light-emitting element 220.

In some cases, since there are errors in the fabrication process of the light-emitting elements 200, the process errors may cause an uneven thickness of the second electrode 25 of the light-emitting element 200, and/or asymmetric thickness of the light-emitting layer, thereby causing the asymmetric viewing angle of the light-emitting element 200. Moreover, it is possible to cause the viewing angle of the light-emitting substrate 1100 to be asymmetric in a certain direction after the light-emitting element 200 is disposed on the substrate 100.

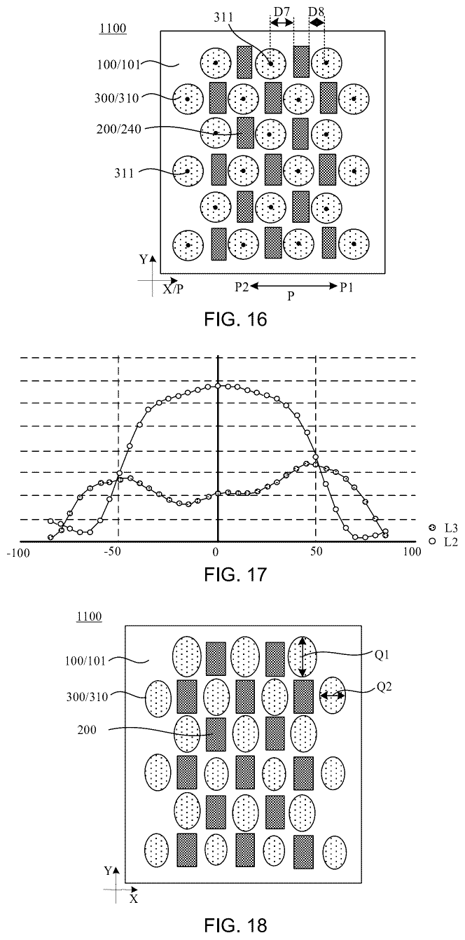

In order to solve the above technical problems, in some embodiments, referring to FIG. 16, the plurality of light-emitting elements 200 include a target light-emitting element 240, and the viewing angle brightness of a first side P1 (i.e., the right side) of the target light-emitting element 240 in a third direction P is greater than the viewing angle brightness of a second side P2 (i.e., the left side) of the target light-emitting element 240 in the third direction P. In a case where the viewing angle brightness of the first side P1 of the target light-emitting element 240 in the third direction P is greater than the viewing angle brightness of the second side P2 of the target light-emitting element 240 in the third direction P, one lens structure 310 is disposed on each of two sides (i.e., the first side P1 and the second side P2) of the target light-emitting element 240 in the third direction P. A distance D8 between the center 311 of the orthogonal projection of the lens structure 310 located on the first side P1 on the first surface 101 and the target light-emitting element 240 is less than a distance D7 between the center 311 of the orthogonal projection of the lens structure 310 located on the second side P2 on the first surface 101 and the target light-emitting element 240, that is, D8<D7. In this way, the convergence effect of the lens structure 310 located on the second side P2 (i.e., the left side) on the light of the target light-emitting element 240 is greater than the convergence effect of the lens structure 310 located on the first side P1 (i.e., the right side) on the light of the target light-emitting element 240, which is conducive to reducing the asymmetry of the viewing angle of the target light-emitting element 240 in the third direction P, and thereby balancing the symmetry of the brightness of the target light-emitting element 240 in the third direction P. The third direction P is the row direction or the column direction in which the plurality of light-emitting element groups 201 are arranged. That is to say, the third direction P may be one of the first direction X and the second direction Y. The first side P1 and the second side P2 are two opposite sides in the third direction P.

The target light-emitting element 240 may be at least one of the first light-emitting element 210, the second light-emitting element 220 and the third light-emitting element 230. For example, the target light-emitting element 240 may include the first light-emitting element 210, or the target light-emitting element 240 may include the second light-emitting element 220, or the target light-emitting element 240 may include the third light-emitting element 230.

For example, as shown in FIG. 17, FIG. 17 is a graph showing simulation results of the light intensity of the light-emitting substrate 1100 at different viewing angles in a case where the target light-emitting element 240 has different brightness in the third direction P at a same viewing angle and the lens structures 310 are disposed at different positions. The curve L2 refers to: as shown in FIG. 16, a graph showing the brightness of the light-emitting element 200 at different viewing angles, in a case where two lens structures 310 are asymmetrically disposed on two sides of the target light-emitting element 240 in the third direction P; the curve L3 refers to: a graph showing the brightness of the light-emitting element 200 at different viewing angles, in a case where two lens structures 310 are symmetrically disposed on two sides of the light-emitting element 200 in the third direction P. In the simulation corresponding to FIG. 17, the orthogonal projection of the light-emitting element 200 on the substrate is in a shape of a rectangle with a length of 40 μm and a width of 20 μm, and the thickness of the light-emitting element 200 is 7 μm (considering only the thicknesses of the first semiconductor layer, the multiple quantum well layer, and the second semiconductor layer); the lens structures are disposed in front, rear, left, and right of the light-emitting element 200, and the orthogonal projections of the lens structures on the substrate each are in a shape of a circle with a diameter of 42 μm, a curvature of the lens structures is 0.05; a distance between the centers of the lens structures oppositely disposed in an extending direction of a short side of the light-emitting element is 70 μm, and a distance between the centers of the lens structures oppositely disposed in an extending direction of a long side of the light-emitting element is 90 μm, the refractive index of the lens structures is 1.6. For the curve L3, the center of the light-emitting element is located between the centers of the lens structures oppositely disposed in the extending direction of the short side of the light-emitting element, and the center of the light-emitting element is located between the centers of the lens structures oppositely disposed in the extending direction of the long side of the light-emitting element. For the curve L2, the center of the light-emitting element is located between the centers of the lens structures oppositely disposed in the extending direction of the long side of the light-emitting element; in the extending direction of the short side of the light-emitting element, a distance between the center of the light-emitting element and the center of the lens structure on the first side is 32.5 μm, and a distance between the center of the light-emitting element and the center of the lens structure on the second side is 37.5 μm, and viewing angle brightness of the first side is greater than viewing angle brightness of the second side.

By comparing the curve L2 and the curve L3, it may be seen that in a case where the target light-emitting element 240 has different brightness in the third direction P at the same viewing angle, the uniformity of the brightness of the target light-emitting element 240 in the third direction P at the same viewing angle may be improved by adjusting the positions of the lens structures 310.

For example, as shown in FIG. 16, the embodiments of the present disclosure are exemplarily described by considering an example in which the third direction P is the first direction X, and the first side P1 is the right side in FIG. 14, and the second side P2 is the left side in FIG. 14. In a case where the viewing angle brightness of the left side of the target light-emitting element 240 is less than the viewing angle brightness of the right side of the target light-emitting element 240, the gap D7 (i.e., the distance D7) between the center 311 of the lens structure 310 located on the left side of the target light-emitting element 240 and the target light-emitting element 240 is greater than the gap D8 (i.e., the distance D8) between the center 311 of the lens structure 310 located on the right side of the target light-emitting element 240 and the target light-emitting element 240. The convergence effect of the lens structure 310 on the left side on the light of the target light-emitting element 240 is greater than the convergence effect of the lens structure 310 on the right side on the light of the target light-emitting element 240, which is conducive to balancing the light-emitting brightness of the left and right sides of the target light-emitting element 240, thereby improving the viewing angle uniformity of the light-emitting element 200 and the light-emitting substrate in the third direction P.

In some embodiments, the orthogonal projection of the lens structure 310 on the first surface 101 is in a shape of at least one of a circle, an ellipse and a rectangle. That is to say, the surface of the lens structure 310 in contact with the cover plate 300 is in a shape of at least one of a circle, an ellipse and a rectangle. For example, the shape of the lens structure 310 may be set according to a shape of the gap between the light-emitting elements 200, so as to increase the area of the orthogonal projection of the lens structure 310 on the first surface 101 as much as possible, thereby increasing the amount of light entering the lens structure 310, improving the light-emitting brightness of the light-emitting element 200 at the front viewing angle, and improving the light-emitting brightness of the light-emitting substrate 1100 in the front view direction. For example, the shape of the orthogonal projection of the lens structure 310 on the first surface 101 is set to a shape of an ellipse or a rectangle, so that the size of the lens structure 310 on the first surface 101 may be increased as much as possible, thereby increasing densities of the lens structures 310 and the light-emitting elements 200 in the light-emitting substrate 1100, thereby increasing a pixel fill rate of the light-emitting substrate 1100 and reducing the grainy feeling of the light-emitting element 200.

For example, as shown in FIGS. 14, 15 and 16, the plurality of lens structures 310 included in the light-emitting substrate 1100 have a same structure, and the orthogonal projections of the plurality of lens structures 310 on the first surface 101 are all in a shape of a circle. Alternatively, as shown in FIG. 18, the plurality of lens structures 310 have a same structure, and the orthogonal projections of the plurality of lens structures 310 on the first surface 101 are all in a shape of an ellipse. Alternatively, the plurality of lens structures 310 have a same structure, and the orthogonal projections of the plurality of lens structures 310 on the first surface 101 are all a shape of a rectangle. The plurality of lens structures 310 have a same structure, which is conducive to improving the structural uniformity of the lens structures 310. In this way, in one aspect, it is possible to reduce the difficulty of fabricating the lens structures 310, in another aspect, it is also possible to improve the light-emitting uniformity of the light-emitting substrate 1100.

In some other embodiments, the plurality of lens structures 310 may also have different structures (e.g., being different in at least one of the shape and size). For example, the orthogonal projections of some lens structures 310 on the first surface 101 are all in a shape of a circle, and the orthogonal projections of some lens structures 310 on the first surface 101 are all in a shape of a rectangle. Alternatively, the orthogonal projections of the plurality of lens structures 310 on the first surface 101 are all in a shape of an ellipse, but the sizes of different lens structures 310 may be different.

In some embodiments, as shown in FIG. 18, the orthogonal projections of the plurality of lens structures 310 on the first surface 101 are in a shape of an ellipse or a rectangle. In this case, the lens structure 310 has a long axis direction Q1 and a short axis direction Q2, and a dimension of the lens structure 310 in the long axis direction Q1 is greater than a dimension of the lens structure 310 in the short axis direction Q2. In a case where the orthogonal projections of the lens structures 310 on the substrate 100 are in a shape of an ellipse, the long axis direction Q1 of the lens structure 310 is the same as a long axis direction of the ellipse, and the short axis direction Q2 of the lens structure 310 is the same as a short axis direction of the ellipse. In a case where the orthogonal projections of the lens structures 310 on the first surface 101 are in a shape of a rectangle, the long axis direction Q1 may be the extending direction of the long side of the rectangle, and the short axis direction Q2 may be the extending direction of the short side of the rectangle.

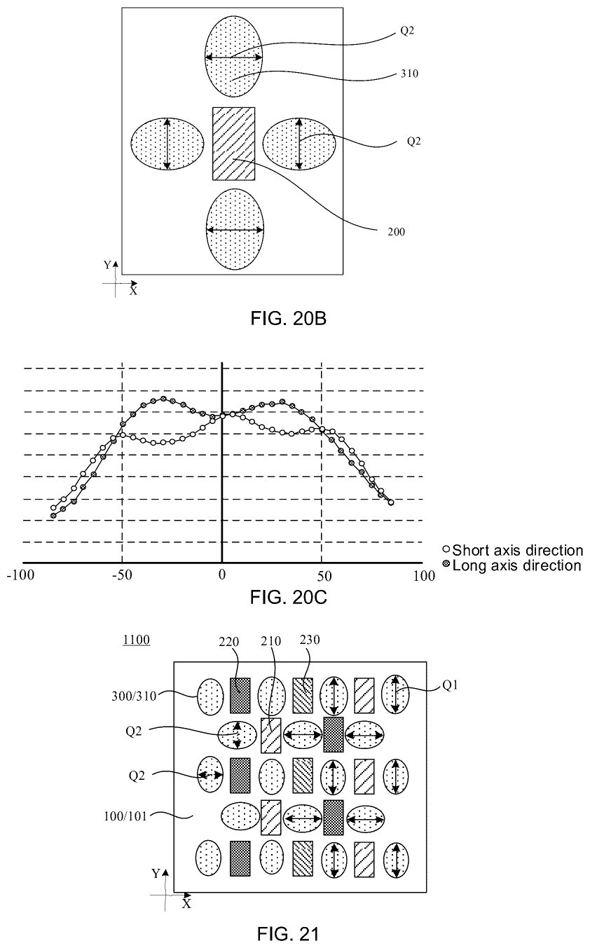

In some embodiments, referring to FIG. 20C, FIG. 20C is a diagram showing the convergence effect of the lens structure 310 in the long axis direction Q1 and the short axis direction Q2 on light. The curve shown by the long axis direction refers to: as shown in FIG. 20A, the brightness of the light-emitting element 200 at different viewing angles, in a case where the long axis direction Q1 of the lens structure 310 is parallel to an extending direction of a side of the light-emitting element 200. The curve shown by the short axis direction refers to: as shown in FIG. 20B, the brightness of the light-emitting element 200 at different viewing angles, in a case where the short axis direction Q2 of the lens structure 310 is parallel to the extending direction of the side of the light-emitting element 200. In the simulation corresponding to FIG. 20C, a length of the light-emitting element 200 is 40 μm, and a width of the light-emitting element 200 is 20 μm, and a thickness of the light-emitting element 200 is 7 μm (considering only the thicknesses of the first semiconductor layer, the multiple quantum well layer, and the second semiconductor layer); the orthogonal projection of the lens structure on the substrate is an ellipse with a long axis of 40 μm and a short axis of 20 μm, the lens structure has a maximum thickness at the center of the lens structure (e.g., the maximum thickness is 25 μm), the refractive index of the lens structure is 1.6; the lens structures are disposed in front, rear, left, and right of the light-emitting element 200; a distance between the centers of the lens structures oppositely disposed in an extending direction of a short side of the light-emitting element is 108 μm, and a distance between the centers of the lens structures oppositely disposed in an extending direction of a long side of the light-emitting element is 128 μm, the center of the light-emitting element is located between the centers of the lens structures oppositely disposed in the extending direction of the short side of the light-emitting element, and the center of the light-emitting element is located between the centers of the lens structures oppositely disposed in the extending direction of the long side of the light-emitting element. When the convergence effect of the long axis direction Q1 on the light of the light-emitting element 200 is tested, the lens structures are disposed on the front, back, left, and right sides of the light-emitting element 200, and the long axis direction Q1 of the lens structure is perpendicular to an extending direction of a line connecting the center of the light-emitting element 200 and the center of the lens structure. When the convergence effect of the short axis direction Q2 on the light of the light-emitting element 200 is tested, the lens structures are disposed on the front, back, left, and right sides of the light-emitting element 200, and the short axis direction Q2 of the lens structure is perpendicular to the extending direction of the line connecting the center of the light-emitting element 200 and the center of the lens structure.

Referring to FIG. 20C, by comparing the curve shown by the long axis direction with the curve shown by the short axis direction, it may be seen that in a case where the long axis direction Q1 of the lens structure 310 is parallel to the extending direction of the side of the light-emitting element 200, the lens structure 310 has a good convergence effect on the light of the light-emitting element.

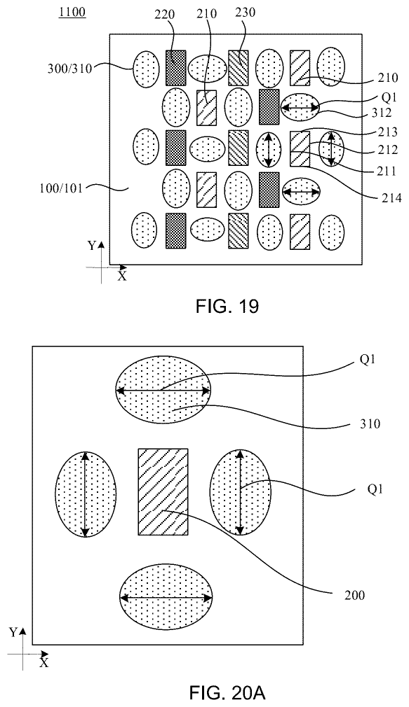

As shown in FIG. 19, the lens structure 310 whose orthogonal projection on the first surface 101 is located on a periphery of the first light-emitting element 210 is a first lens structure 312, and the long axis direction Q1 of the first lens structure 312 is parallel to an extending direction of a border of the first light-emitting element 210 proximate to the first lens structure 312. In other words, the long axis direction Q1 of the first lens structure 312 is perpendicular to an extending direction of a line connecting a center of the first light-emitting element 210 and a center of the first lens structure 312. In this way, it is conducive to increasing an area of a surface of the first lens structure 312 facing the first light-emitting element 210, so as to increase the amount of light emitted by the first light-emitting element 210 to the first lens structure 312, thereby increasing the amount of light exiting from the first light-emitting element 210 in the front view direction, and improving the brightness uniformity of the first light-emitting element 210, the second light-emitting element 220 and the third light-emitting element 230 in the front view direction.

For example, as shown in FIG. 19, the embodiments of the present disclosure are exemplarily described by considering an example in which the orthogonal projections of the plurality of lens structures 310 on the first surface 101 are in a shape of an ellipse. A left side 211 and a right side 212 of the first light-emitting element 210 each extend in the second direction Y. In this case, the long axis directions Q1 of two first lens structures 312 located on the left and right sides of the first light-emitting element 210 each extend in the second direction Y. An upper side 213 and a lower side 214 of the first light-emitting element 210 each extend in the first direction X. In this case, the long axis directions Q1 of two first lens structures 312 located on the upper side and the lower side of the first light-emitting element 210 each extend in the first direction X.

In some embodiments, referring to FIG. 21, the orthogonal projection of the lens structure 310 on the substrate 100 is in a shape of at least one of an ellipse and a rectangle. FIG. 21 exemplarily illustrates the embodiments of the present disclosure by considering an example in which the orthogonal projections of the lens structures 310 on the substrate 100 are in a shape of only an ellipse. The lens structure 310 has the long axis direction Q1 and the short axis direction Q2, and a dimension of the lens structure 310 in the long axis direction Q1 is greater than a dimension of the lens structure 310 in the short axis direction Q2. The plurality of lens structures 310 are arranged in a plurality of rows, and one row includes a plurality of lens structures 310 arranged in the first direction X. The long axis directions Q1 of the lens structures 310 in a same row are parallel to each other, and the long axis directions Q1 of the lens structures 310 in two adjacent rows intersect with each other. For example, in two adjacent rows of lens structures 310, the long axis directions Q1 of one row of lens structures 310 are parallel to the first direction X, and the long axis directions Q1 of the other row of lens structures 310 are parallel to the second direction Y. In a case where the first direction X is perpendicular to the second direction Y, the long axis directions Q1 of two adjacent rows of lens structures 310 are perpendicular to each other. In this way, the densities of the lens structures 310 and the light-emitting elements 200 in the light-emitting substrate 1100 are increased, thereby improving the pixel fill rate of the light-emitting substrate 1100 and reducing the grainy feeling of the light-emitting element 200. In a case where the orthogonal projection of the lens structure 310 on the substrate 100 is in a shape of an ellipse, the long axis direction Q1 of the lens structure 310 is the same as a long axis direction of the ellipse, and the short axis direction Q2 of the lens structure 310 is the same as a short axis direction of the ellipse. In a case where the orthogonal projection of the lens structure 310 on the substrate 100 is in a shape of a rectangle, the long axis direction of the lens structure 310 is the same as a long side direction of the rectangle, and the short axis direction of the lens structure 310 is the same as a short side direction of the rectangle.

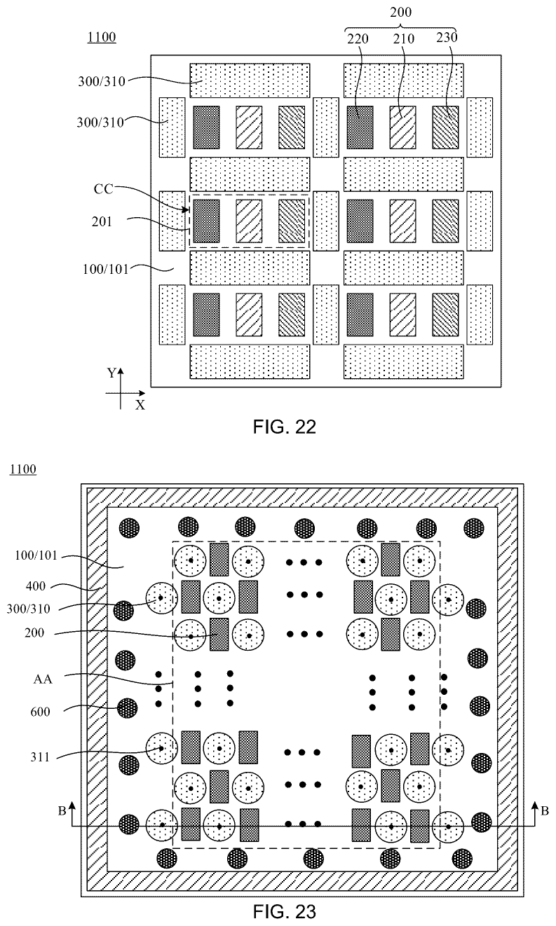

It may be understood that the arrangement of the long axis direction Q1 and short axis direction Q2 of the lens structure 310 described above is also applicable to the light-emitting element group 201 including a plurality of light-emitting elements 200. For example, as shown in FIG. 22, in a case where the light-emitting element group 201 includes one first light-emitting element 210, one second light-emitting element 220, and one third light-emitting element 230 arranged adjacent in the first direction X, a region defined by an outer contour of the light-emitting element group 201 is a first region CC, and the first direction X is a row direction in which the plurality of light-emitting elements 200 are arranged. In this case, the long axis direction Q1 of the lens structure 310 is parallel to an extending direction of a side of the first region CC proximate to the lens structure 310, and the structure of the lens structure 310 is not repeated herein.

In some other embodiments, referring to FIG. 22, the plurality of light-emitting elements 200 are arranged in a standard manner (or referred to as a strip arrangement). In this case, a gap between at least two light-emitting elements 200 is small, which is insufficient to provide the lens structure 310 between any two light-emitting elements 200.

On this basis, the plurality of light-emitting elements 200 include a plurality of light-emitting element groups 201, and each light-emitting element group 201 includes at least two light-emitting elements 200. The light-emitting element group 201 may be the minimum combination unit of the plurality of light-emitting elements 200, and is the minimum unit capable of displaying full colors. For example, in a case where the plurality of light-emitting elements 200 include the plurality of first light-emitting elements 210, the plurality of second light-emitting elements 220 and the plurality of third light-emitting elements 230, one light-emitting element group 201 may include one first light-emitting element 210, one second light-emitting element 220 and one third light-emitting element 230. Of course, the embodiments of the present disclosure are not limited thereto, and any other suitable division manner of the light-emitting element group may be adopted as long as the same technical concept is adopted.

A gap between two adjacent light-emitting elements 200 in a same light-emitting element group 201 is less than a gap between two adjacent light-emitting element groups 201. On this basis, the lens structure 310 may be disposed between adjacent light-emitting element groups 201. That is to say, the orthogonal projection of the lens structure 310 on the first surface 101 is located between adjacent light-emitting element groups 201. In this way, in one aspect, it is conducive to increasing a space for the arrangement of the lens structure 310, and it is conducive to further increasing the size of the lens structure 310, so as to increase the amount of light incident on the lens structure 310, and improve the convergence effect of the lens structure on the light of the light-emitting element 200, and increase the amount of light exiting from the light-emitting substrate 1100 in the front view direction. Moreover, it is also possible to improve the light mixing effect of the plurality of light-emitting elements 200 in the light-emitting element group 201, and improve the color purity and uniformity of the white light of the light-emitting substrate.

For example, considering the arrangement of the light-emitting elements 200 shown in FIG. 22 as an example, one light-emitting element group 201 includes three light-emitting elements 200 arranged at intervals in the first direction X, and a region where the three light-emitting elements 200 are located is in a shape of a rectangle. On this basis, the orthogonal projections of the lens structures 310 on the first surface 101 each may be set to a shape of a rectangle around the light-emitting element group 201, which may increase the utilization rate of the space between the light-emitting element groups 201 as much as possible, thereby increasing the size of the lens structure 310, so that the amount of light incident on the lens structure 310 may be increased, the convergence effect of the lens structure 310 on the light of the light-emitting element 200 may be enhanced, and the brightness of the light-emitting substrate 1100 in the front view direction may be increased.

With continued reference to FIG. 22, the lens structures 310 arranged side by side with the light-emitting element groups 201 in the first direction X may have a different shape and size from the lens structures 310 arranged side by side with the light-emitting element groups 201 in the second direction Y, so that the sizes of the lens structures 310 at different positions may be increased as much as possible, and the convergence effect of the lens structure 310 on the light of the light-emitting element 200 may be enhanced as much as possible, and the brightness of the light-emitting substrate 1100 in the front view direction may be increased.

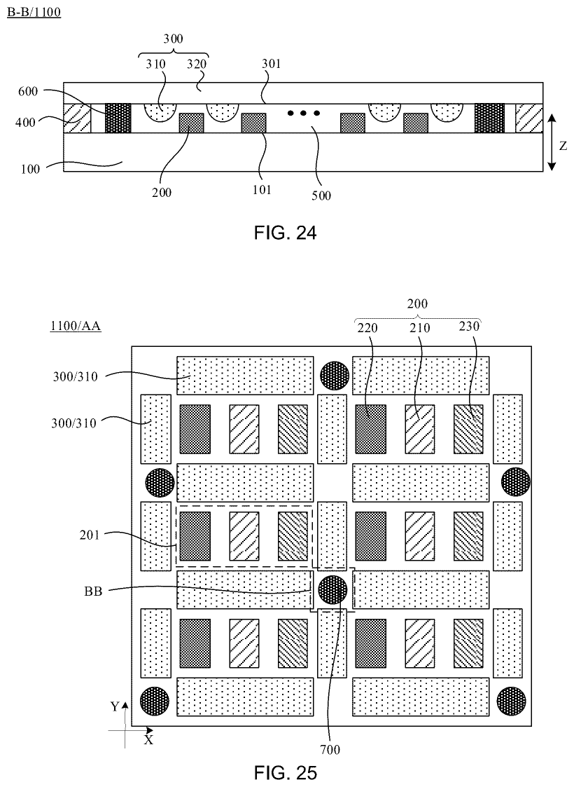

In some embodiments, referring to FIGS. 23 and 24, the light-emitting substrate 1100 further includes a light-emitting region AA defined by outer contours of the outermost light-emitting elements 200. The light-emitting substrate further includes first support pillar(s) 600 located between the substrate 100 and the cover plate 300. The first support pillar 600 is in contact with both the substrate 100 and the cover plate 300. Orthogonal projections of the first support pillars 600 on the substrate 100 are disposed around the light-emitting region AA. The first support pillar 600 may enhance the support effect between the substrate 100 and the cover plate 300 and reduce the risk of collapse between the substrate 100 and the cover plate 300.

In a case where the light-emitting substrate 1100 includes the sealing portion 400 and the filling portion 500, the orthogonal projection of the first support pillar 600 on the substrate 100 is located between an orthogonal projection of the sealing portion 400 on the substrate 100 and the light-emitting region AA. For example, as shown in FIG. 23, the light-emitting substrate 1100 includes a plurality of first support pillars 600. The plurality of first support pillars 600 may be disposed around the light-emitting region AA, and there may be gaps between the first support pillar 600 and the light-emitting element 200, between the first support pillar 600 and the lens structure 310 and between the first support pillar 600 and the sealing portion 400, so that the risk of interference between the first support pillars 600 and the light-emitting elements 200, the lens structures 310 and the sealing portion 400 may be reduced.

For example, as shown in FIG. 25, the light-emitting substrate 1100 may include both second support pillar(s) 700 and the first support pillar(s) 600, and the second support pillar 700 is located within the light-emitting region AA. For example, the first support pillar 600 and the second support pillar 700 may be photo spacers (PS). The light-emitting substrate 1100 may include both the second support pillar 700 and the first support pillar 600, which may be suitable for a situation where the light-emitting substrate 1100 has a large size (that is, in a case where the light-emitting region AA is in a shape of a rectangle or approximately a rectangle, a diagonal length of the light-emitting region is greater than 6 inches or 10 inches), so that the light-emitting substrate may be provided with a good support. In some embodiments, referring to FIG. 25, in a case where the plurality of light-emitting elements 200 are arranged in the strip arrangement as shown in FIG. 25, one lens structure 310 is disposed between two adjacent light-emitting element groups 201 in the first direction X, and one lens structure 310 is disposed between two adjacent light-emitting element groups 201 in the second direction Y. End portions proximate to each other, of four lens structures 310 located among four light-emitting element groups 201 in two adjacent rows and two columns, form a second region BB. The light-emitting substrate 1100 may further include a plurality of second support pillars 700, one second support pillar 700 is located in one second region BB, and the second support pillars 700 are in contact with both the substrate 100 and the cover plate 300. The second support pillars 700 may further enhance the support effect between the substrate 100 and the cover plate 300, and reduce the risk of collapse between the substrate 100 and the cover plate 300.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting substrate, comprising: a substrate, a cover plate, and a plurality of light-emitting elements located on the substrate, the plurality of light-emitting elements being located between the substrate and the cover plate; and
the cover plate including a plurality of lens structures protruding toward the substrate, wherein orthogonal projections of centers of the plurality of lens structures on the substrate are located outside orthogonal projections of the plurality of light-emitting elements on the substrate, and an orthogonal projections of at least one of the plurality of lens structures on the substrate is located between the orthogonal projections of adjacent light-emitting elements in the plurality of light-emitting elements on the substrate.

2. The light-emitting substrate according to claim 1, wherein the light-emitting substrate further comprises a sealing portion and a filling portion, the sealing portion, the substrate and the cover plate together form a closed space surrounding the filling portion;
wherein a refractive index of the filling portion is less than a refractive index of the plurality of lens structures.

3. (canceled)

4. The light-emitting substrate according to claim 1, wherein
the cover plate further includes an extension portion extending in a plane extending parallel to the substrate, the extension portion is located on a side of the plurality of lens structures away from the substrate, and the extension portion is connected to the plurality of lens structures; or
the cover plate for er includes the extension portion extending in the plane extending parallel to the substrate, the extension portion is located on the side of the plurality of lens structures away from the substrate, and the extension portion is connected to the plurality of lens structures; the plurality of lens structures and the extension portion are a one-piece structure.

5. (canceled)

6. (canceled)

7. The light-emitting substrate according to claim 1, wherein a surface of a region of the cover plate located between adjacent lens structures in the plurality of lens structures facing the substrate is conformal with an extending surface of the substrate.

8. (canceled)

9. The light-emitting substrate according to claim 1, wherein the lens structure has an area of a section that decreases in a direction towards the substrate; an extending direction of the section is parallel to an extending direction of the substrate opposite to the lens structure.

10. The light-emitting substrate according to claim 1, wherein
the light-emitting substrate further comprises a light-emitting region defined by outer contours of outermost two or more light-emitting elements in the plurality of light-emitting elements;
the light-emitting substrate further comprises first support pillar(s) located between the substrate and the cover plate, and the first support pillar is in contact with both the substrate and the cover plate;
wherein orthogonal projections of the first support pillars on the substrate are disposed around the light-emitting region.

11. The light-emitting substrate according to claim 10, wherein the light-emitting substrate further comprises a sealing portion and a filling portion, the sealing portion, the substrate and the cover plate together form a closed space surrounding the filling portion; and
the orthogonal projections of the first support pillars on the substrate are located between an orthogonal projection of the sealing portion on the substrate and the light-emitting region.

12. (canceled)

13. (canceled)

14. The light-emitting substrate according to claim 1, wherein the plurality of light-emitting elements include a plurality of light-emitting element groups, a light-emitting element group in the plurality of light-emitting element groups includes at least one light-emitting element in the plurality of light-emitting elements, the plurality of light-emitting element groups are arranged in a plurality of rows and a plurality of columns, two adjacent light-emitting element groups respectively belonging to two adjacent rows are disposed in a staggered manner in a first direction, and two adjacent light-emitting element groups respectively belonging to two adjacent columns are disposed in a staggered manner in a second direction; the first direction is a row direction in which the plurality of light-emitting element groups are arranged, and the second direction is a column direction in which the plurality of light-emitting element groups are arranged; and
the orthogonal projection of the lens structure on the substrate is located between adjacent light-emitting element groups in the plurality of light-emitting element groups and has a gap from the adjacent light-emitting element groups.

15. The light-emitting substrate according to claim 14, wherein the light-emitting element group includes a light-emitting element in plurality of light-emitting elements;
the plurality of light-emitting elements include a plurality of first light-emitting elements, a plurality of second light-emitting elements, and a plurality of third light-emitting elements, one of the first light-emitting element, the second light-emitting element, and the third light-emitting element is configured to emit red light, another of the first light-emitting element, the second light-emitting element, and the third light-emitting element is configured to emit green light, and yet another of the first light-emitting element, the second light-emitting element, and the third light-emitting element is configured to emit blue light; and
a line connecting centers of orthogonal projections of the first light-emitting element, the second light-emitting element, and the third light-emitting element that are closest to each other on the substrate is in a shape of a triangle.

16. The light-emitting substrate according to claim 15, wherein
a maximum length of the orthogonal projection of the lens structure on the substrate in the first direction is less than or equal to a distance between two light-emitting elements adjacent to the lens structure in the first direction; and/or
a maximum length of the orthogonal projection of the lens structure on the substrate in the second direction is less than or equal to a distance between two light-emitting elements adjacent to the lens structure in the second direction.

17. The light-emitting substrate according to claim 15, wherein
in the first direction, the orthogonal projection of the center of the lens structure on the substrate has a same gap from two light-emitting elements adjacent to the lens structure in the plurality of light-emitting elements; and/or
in the second direction, the orthogonal projection of the center of the lens structure on the substrate has a same gap from two light-emitting elements adjacent to the lens structure in the plurality of light-emitting elements.

18-21. (canceled)

22. The light-emitting substrate according to claim 15, wherein
in the first direction, a distance between the center of the orthogonal projection of the lens structure on the substrate and the first light-emitting element is greater than a distance between the center of the orthogonal projection of the lens structure on the substrate and the second light-emitting element, and is greater than a distance between the center of the orthogonal projection of the lens structure on the substrate and the third light-emitting element, and/or
in the second direction, a distance between the center of the orthogonal projection of the lens structure on the substrate and the first light-emitting element is greater than a distance between the center of the orthogonal projection of the lens structure on the substrate and the second light-emitting element, and is greater than a distance between the center of the orthogonal projection of the lens structure on the substrate and the third light-emitting element.

23. The light-emitting substrate according to claim 15, wherein the plurality of light-emitting elements include a target light-emitting element, and a viewing angle brightness of a first side of the target light-emitting element in a third direction is greater than a viewing angle brightness of a second side of the target light-emitting element in the third direction; the third direction is parallel to the first direction or the second direction;
a lens structure in the plurality of lens structures is disposed on each of two sides of the target light-emitting element in the third direction, and a distance between the orthogonal projection of the center of the lens structure located on the first side of the target light-emitting element on the substrate and the target light-emitting element is less than a distance between the orthogonal projection of the center of the lens structure located on the second side of the target light-emitting element on the substrate and the target light-emitting element; and
the target light-emitting element is at least one of the first light-emitting element, the second light-emitting element, and the third light-emitting element.

24. The light-emitting substrate according to claim 15, wherein
the orthogonal projection of the lens structure on the substrate is in a shape of at least one of an ellipse and a rectangle, the lens structure has a long axis direction and a short axis direction, and a dimension of the lens structure in the long axis direction is greater than a dimension of the lens structure in the short axis direction;
the lens structure located on a periphery of the first light-emitting element in the plurality of lens structures is a first lens structure; the long axis direction of the first lens structure is perpendicular to a direction of a line connecting the center of the first light-emitting element and the center of the first lens structure;
wherein in a case where the orthogonal projection of the lens structure on the substrate is in a shape of the ellipse, the long axis direction of the lens structure is the same as a long axis direction of the ellipse, and the short axis direction of the lens structure is the same as a short axis direction of the ellipse; in a case where the orthogonal projection of the lens structure on the substrate is in a shape of the rectangle, the long axis direction of the lens structure is the same as a long side direction of the rectangle, and the short axis direction of the lens structure is the same as a short side direction of the rectangle.

25. The light-emitting substrate according to claim 15, wherein
the orthogonal projection of the lens structure on the substrate is in a shape of at least one of an ellipse and a rectangle, the lens structure has a long axis direction and a short axis direction, and a dimension of the lens structure in the long axis direction is greater than a dimension of the lens structure in the short axis direction;
the plurality of lens structures are arranged in a plurality of rows, and one row includes two or more lens structures arranged in the first direction; the long axis directions of the lens structures in a same row are parallel to each other, and the long axis directions of the lens structures in two adjacent rows intersect with each other;
wherein in a case where the orthogonal projection of the lens structure on the substrate is in a shape of the ellipse, the long axis direction of the lens structure is the same as a long axis direction of the ellipse, and the short axis direction of the lens structure is the same as a short axis direction of the ellipse; in a case where the orthogonal projection of the lens structure on the substrate is in a shape of the rectangle, the long axis direction of the lens structure is the same as a long side direction of the rectangle, and the short axis direction of the lens structure is the same as a short side direction of the rectangle.

26. The light-emitting substrate according to claim 22, wherein the first light-emitting element is configured to emit red light;
one of the second light-emitting element and the third light-emitting element is configured to emit green light, and another of the second light-emitting element and the third light-emitting element is configured to emit blue light.

27. The light-emitting substrate according to claim 1, wherein the plurality of light-emitting elements include a plurality of light-emitting element groups, and each light-emitting element group in the plurality of light-emitting element groups includes at least two light-emitting elements in the plurality of light-emitting elements; a gap between two adjacent light-emitting elements in a same light-emitting element group is less than a gap between two adjacent light-emitting element groups in the plurality of light-emitting element groups; and
the orthogonal projection of the lens structure on the substrate is located between the two adjacent light-emitting element groups and has a gap from the adjacent light-emitting element groups.

28. The light-emitting substrate according to claim 27, wherein
the plurality of light-emitting elements include a plurality of first light-emitting elements, a plurality of second light-emitting elements, and a plurality of third light-emitting elements, one of the first light-emitting element, the second light-emitting element, and the third light-emitting element is configured to emit red light, another of the first light-emitting element, the second light-emitting element, and the third light-emitting element is configured to emit green light, and yet another of the first light-emitting element, the second light-emitting element, and the third light-emitting element is configured to emit blue light; the light-emitting element group includes the first light-emitting element, the second light-emitting element, and the third light-emitting element arranged adjacent in a first direction, and a region defined by an outer contour of the light-emitting element group is a first region; the first direction is a row direction in which the plurality of light-emitting elements are arranged;
the orthogonal projection of the lens structure on the substrate is in a shape of at least one of an ellipse and a rectangle, the lens structure has a long axis direction and a short axis direction, and a dimension of the lens structure in the long axis direction is greater than a dimension of the lens structure in the short axis direction;
the long axis direction of the lens structure is parallel to an extending direction of a side of the first region proximate to the lens structure;
wherein in a case where the orthogonal projection of the lens structure on the substrate is in a shape of the ellipse, the long axis direction of the lens structure is the same as a long axis direction of the ellipse, and the short axis direction of the lens structure is the same as a short axis direction of the ellipse; in a case where the orthogonal projection of the lens structure on the substrate is in a shape of the rectangle, the long axis direction of the lens structure is the same as a long side direction of the rectangle, and the short axis direction of the lens structure is the same as a short side direction of the rectangle.

29-33. (canceled)

34. The light-emitting substrate according to claim 1, wherein the plurality of light-emitting elements are a mini light-emitting diode (Mini-LED) or a micro light-emitting diode (Micro-LED).

35. A display module, comprising the light-emitting substrate according to claim 1.
